(19) United States
(12) Patent Application Publication
(10) Pub. No.: US 2026/0329538 A1
(43) Pub. Date: Oct. 22, 2026

(54) PARTIAL PRECISION ANALOG-DIGITAL COMPUTING WITH BIT-LEVEL SPLICING

(71) Applicant: Koushik Krishnan, Saratoga, CA (US)

(72) Inventor: Koushik Krishnan, Saratoga, CA (US)

(21) Appl. No.: 19/639,324

(22) Filed: Apr. 6, 2026

Related U.S. Application Data
(60) Provisional application No. 63/791,110, filed on Apr. 18, 2025.
(60) Provisional application No. 63/819,003, filed on Jun. 6, 2025.

(51) Int. Cl. G06F 7/523; G06F 5/01; G06F 7/50; G06F 7/544; H03M 1/12; H03M 1/66

(52) U.S. Cl. CPC G06F 7/523; G06F 5/01; G06F 7/50; G06F 7/5443; H03M 1/122; H03M 1/662

(57) ABSTRACT

Partial precision analog-digital computing with bit splicing is provided. A multiplier circuit comprises an array of current generation units, each generating a current output corresponding to a respective bit-spliced portion of a first digital operand. The multiplier circuit further comprises a signal generation unit that generates pulse inputs corresponding to bit-spliced portions of a second digital operand, a switching unit comprising switches coupled to the current generation units, and an integration unit comprising integrator circuits coupled to the switches. Applying each pulse input to a respective switch in a systolic manner gates the current output to a respective integrator circuit. The integrator circuits are reset between successive cycles to produce voltage outputs corresponding to pairwise partial products. A digital processing unit digitizes the voltage outputs and combines partial products using binary shift and add operations to reconstruct a full-precision multiplication result.

### CROSS-REFERENCE TO RELATED APPLICATIONS/INCORPORATION BY REFERENCE

This application claims priority to U.S. Provisional Patent Application Ser. No. 63/791,110 filed on Apr. 18, 2025, and U.S. Provisional Patent Application Ser. No. 63/819,003 filed on Jun. 6, 2025, the entire content of which is hereby incorporated herein by reference.

### TECHNICAL FIELD

The disclosure relates to signal processing systems and more particularly, to methods and systems for partial precision analog-digital computing with bit-level splicing.

### BACKGROUND

Modern computing systems face increasing demands for performing arithmetic operations such as multiplication and accumulation with high throughput and energy efficiency. These operations are fundamental to a wide range of applications, including machine learning inference, neural network training, digital signal processing, and scientific computing. As workloads continue to grow in complexity and scale, the computational requirements for these arithmetic primitives have become increasingly challenging to meet with conventional approaches. A significant challenge in performing high-precision arithmetic operations arises from the relationship between operand bit width and hardware complexity. When multiplying two N-bit operands, the resulting product requires up to 2N bits to represent without loss of precision. Furthermore, when accumulating multiple products, as in multiply-accumulate operations, additional bits are needed to accommodate the sum without overflow. For example, accumulating N products of b-bit operands may require p+2b bits of precision, where p equals log base 2 of N. This exponential growth in precision requirements translates directly to increased hardware area, power consumption, and design complexity. Managing this relationship between operand precision and hardware resources remains a persistent challenge in the design of efficient arithmetic circuits.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In various embodiments of the disclosure, a multiplier circuit is described. The multiplier circuit includes an array of current generation units. Each current generation unit of the array of current generation units is configured to generate a current output corresponding to a respective bit-spliced portion of a first set of bit-spliced portions of a first digital operand. The multiplier circuit further includes a signal generation unit configured to generate a set of pulse inputs corresponding to a second set of bit-spliced portions of a second digital operand. The multiplier circuit also includes a switching unit comprising an array of switches respectively coupled to the array of current generation units. The multiplier circuit additionally includes an integration unit comprising an array of integrator circuits respectively coupled to the array of switches. Applying each pulse input of the set of pulse inputs to a respective switch of the array of switches in a systolic manner gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. The multiplier circuit further includes a digital processing unit configured to digitize the set of voltage outputs into a set of digitized partial products and combine the set of digitized partial products based on binary shift and add operations to reconstruct a full-precision multiplication result of the first digital operand and the second digital operand.

As used herein, the term “systolic manner” refers to a data flow pattern in which pulse inputs corresponding to bit-spliced portions of a digital operand are sequentially shifted through an array of switches across successive cycles. In the systolic manner, during a first cycle, a first pulse input is applied to a first switch of the array of switches. During a second cycle, the first pulse input shifts to a second switch while a second pulse input is introduced to the first switch. This sequential shifting pattern continues through remaining cycles, with each pulse input propagating to a next switch in the array while a subsequent pulse input enters the first switch, until all pulse inputs have been applied to all switches of the array.

In various embodiments of the disclosure, a multiply-accumulate (MAC) circuit is described. The MAC circuit includes a plurality of multiplier circuits, each multiplier circuit of the plurality of multiplier circuits comprising an array of current generation units. Each current generation unit of the array of current generation units is configured to generate a current output corresponding to a respective bit-spliced portion of a first set of bit-spliced portions of a respective first digital operand. Each multiplier circuit further comprises a signal generation unit configured to generate a set of pulse inputs corresponding to a second set of bit-spliced portions of a respective second digital operand. Each multiplier circuit also comprises a switching unit comprising an array of switches respectively coupled to the array of current generation units, wherein applying each pulse input of the set of pulse inputs to a respective switch of the array of switches gates the current output from a respective current generation unit of the array of current generation units. The MAC circuit further includes a shared array of integrator circuits. Current outputs from corresponding bit positions across the plurality of multiplier circuits are shorted together before integration such that the shared array of integrator circuits accumulates summed currents from the plurality of multiplier circuits. The shared array of integrator circuits is reset between successive cycles such that the shared array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions accumulated across the plurality of multiplier circuits. The MAC circuit further includes an ADC array configured to digitize the set of voltage outputs from the shared array of integrator circuits into a set of digitized partial products, and a digital reconstruction unit configured to combine the set of digitized partial products based on binary shift and add operations to produce a MAC result.

In various embodiments of the disclosure, a method for performing hybrid analog-digital multiplication is described. The method includes generating, by an array of current generation units, a plurality of current outputs. Each current output corresponds to a respective bit-spliced portion of a first set of bit-spliced portions of a first digital operand. The method further includes generating, by a signal generation unit, a set of pulse inputs corresponding to a second set of bit-spliced portions of a second digital operand. The method also includes applying each pulse input of the set of pulse inputs to a respective switch of an array of switches in a systolic manner to gate a current output of the plurality of current outputs from a respective current generation unit of the array of current generation units to a respective integrator circuit of an array of integrator circuits. The method additionally includes resetting the array of integrator circuits between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. The method further includes digitizing, by a digital processing unit, the set of voltage outputs into a set of digitized partial products. The method also includes combining, by the digital processing unit, the set of digitized partial products based on shift and add operations to reconstruct a full-precision multiplication result of the first digital operand and the second digital operand.

The foregoing general description of the illustrative embodiments and the following detailed description thereof are merely exemplary aspects of the teachings of this disclosure and are not restrictive.

Additional technical features and benefits are realized through the techniques of the disclosure. Embodiments and aspects of the disclosure are described in detail herein and are considered a part of the claimed subject matter. For a better understanding, refer to the detailed description and the drawings.

### BRIEF DESCRIPTION OF THE DRAWINGS

The following description will provide details of preferred embodiments with reference to the following figures, wherein:

FIG. 1 is a diagram that illustrates a multiplier circuit for partial precision analog computing with bit splicing, in accordance with an embodiment of the disclosure;

FIG. 2 is a diagram that illustrates a modulated current element for partial precision analog computing operations, in accordance with an embodiment of the disclosure;

FIG. 3 is a diagram that illustrates a master modulated current element comprising multiple modulated current elements, in accordance with an embodiment of the disclosure;

FIG. 4 is a block diagram that illustrates the master modulated current element of FIG. 3 configured for broadcast mode operation, in accordance with an embodiment of the disclosure;

FIG. 5 is a block diagram that illustrates a pipelined implementation of the master modulated current element of FIG. 3 for processing multiple instances of digital operands, in accordance with an embodiment of the disclosure;

FIG. 6 is a block diagram that illustrates the master modulated current element of FIG. 3 configured for broadcast mode operation with systolic data flow, in accordance with an embodiment of the disclosure;

FIG. 7 is a block diagram that illustrates a multiply-accumulate circuit comprising a plurality of multiplier circuits, in accordance with an embodiment of the disclosure;

FIG. 8 is a block diagram that illustrates a multiply-accumulate circuit with shared integrator circuits, in accordance with an embodiment of the disclosure; and

FIG. 9 is a flowchart that illustrates a method for performing hybrid analog-digital multiplication using partial precision and bit splicing techniques, in accordance with an embodiment of the disclosure.

FIG. 10 is a block diagram that illustrates a multiplier circuit comprising a memory array, a current array, a switch array, an integrator unit, an A/D conversion unit, and a reconstruction unit for partial precision analog computing with bit splicing, in accordance with an embodiment of the disclosure; and

FIG. 11 is a block diagram that illustrates a MAC circuit comprising a plurality of CIM blocks with a shared summation node, an integrator unit, an A/D conversion unit, and a reconstruction unit for partial precision analog computing, in accordance with an embodiment of the disclosure.

### DETAILED DESCRIPTION

Analog computing systems have emerged as a promising approach for performing arithmetic operations, particularly multiplication and multiply-and-accumulate (MAC) operations that form the computational foundation of many signal processing and machine learning applications. These systems may leverage current-mode and time-domain processing techniques to perform multiplication operations in the analog domain, offering potential advantages in power efficiency and computational density compared to conventional digital implementations. However, analog computing systems face a fundamental precision challenge when performing high-precision arithmetic operations, whether for individual multiplication operations or when multiple operands are combined in MAC operations.

In analog computing systems employing Modulated Current Elements (MCE) for multiplication and MAC operations, the multiplication of two operands x and w produces a product x·w, while the MAC computation may be expressed as MAC=Σxᵢ·wᵢ, where xᵢ represents input values and wᵢ represents weight values. When each operand x and w (or xᵢ and wᵢ) is b bits in length, each product x·w (or xᵢ·wᵢ) may require up to 2b bits to represent the full-precision result. For MAC operations, summing N products adds another log₂N bits to accommodate the accumulated result without overflow. The total precision requirement for a single multiplication operation may therefore be expressed as 2b bits, while for MAC operations the requirement may be expressed as p+2b bits, where p=log₂N represents the additional bits needed for accumulation.

For example, when 8-bit operands are used for a single multiplication operation, the full precision requirement becomes 8+8=16 bits. When 8-bit operands are used with N=4 entries in a MAC operation, the full precision requirement becomes 8+8+log₂(4) =8+8+2=18 bits. These precision requirements have direct implications for the analog-to-digital converter (ADC) that converts the analog output voltage to a digital result. For multiplication operations, the ADC may be required to support an effective number of bits (ENOB) equal to 2b bits, while for MAC operations the ADC may be required to support p+2b bits to preserve the full precision of the computation. Additionally, circuits within the MCE may be required to meet noise and matching specifications corresponding to the required precision, which increases design complexity for both the MCE and ADC components.

The precision challenge extends to the current digital-to-analog converter (DAC) implementation within the analog computing system for both multiplication and MAC operations. A conventional current-mode DAC for N-bit operations may require current sources scaled in a binary-weighted fashion as I₀, 2I₀, 4I₀, and continuing to 2^{N}·I₀. This exponential growth in current levels leads to a corresponding increase in the area required for implementation. For an 8-bit current DAC, the implementation may consume 255·Aᵤ area, where Aᵤ represents the unit area of a unit element that produces the unit current Iᵤ. The summation Σ(k=0 to N−1) 2^{k}=255 for N=8 illustrates the exponential growth in component count. This exponential growth in area, power consumption, and design complexity makes full-precision analog multiplication and MAC implementations impractical for high-resolution systems.

The present disclosure describes a bit splicing technique that addresses the precision challenge for both multiplication and MAC operations by splitting operands into smaller chunks and processing the chunks across multiple cycles. Instead of processing full N-bit values in a single operation, the operands may be divided into smaller portions, such as 2-bit slices, and each portion may be processed in a separate cycle. The partial results from each cycle may then be combined through digital post-processing to reconstruct the full-precision result for either a single multiplication or a MAC operation.

The bit splicing technique may be represented mathematically by expressing each operand as a combination of multiple bit-spliced portions. The number of bit-spliced portions and the bit width of each portion may be configured based on the total bit width of the operands and the desired trade-off between cycle count and hardware complexity. For example, an 8-bit operand may be split into four 2-bit portions, two 4-bit portions, or other combinations. Similarly, a 16-bit operand may be split into eight 2-bit portions, four 4-bit portions, two 8-bit portions, or other variations. For operands X and Y in a multiplication operation with two bit-spliced portions each, the representation may be expressed as X=Aφ+B and Y=Cφ+D, where A and B represent the most significant bit (MSB) and least significant bit (LSB) portions of X respectively, C and D represent the MSB and LSB portions of Y respectively, and φ=2^{p} where p is the number of bits in each portion. The multiplication of X and Y may then be expanded as X·Y=(Aφ+B)(Cφ+D)=AC·φ²+(AD+BC)·φ+BD. For operands split into more than two portions, such as four 2-bit portions for an 8-bit operand, the expansion generalizes to include all pairwise partial products of the bit-spliced portions, with each partial product weighted according to the combined significance of its constituent portions. For MAC operations, this expansion is applied to each product xᵢ·wᵢ in the summation, with the partial products accumulated according to their significance levels.

The final result for both multiplication and MAC operations may be reconstructed using shift and add operations in the digital domain. For a multiplication with two bit-spliced portions per operand, the reconstruction may be expressed as Result=BD+(AD+BC) [symbol] p+AC [symbol] 2p, where the notation [symbol] p denotes a left shift by p bits, which is equivalent to multiplying by 2^{p}. For operands split into more than two portions, the reconstruction involves shifting each partial product by an amount corresponding to the sum of the bit positions of its constituent portions and adding all shifted partial products together. For example, when an 8-bit operand is split into four 2-bit portions (w₃, w₂, w₁, w₀) and another 8-bit operand is split into four 2-bit portions (x₃, x₂, x₁, x₀), the reconstruction involves sixteen partial products, each shifted by (i+j)×p bits where i and j are the portion indices and p is the bit width of each portion. For MAC operations, the partial products from each multiplier circuit are first reconstructed using the same shift and add operations, and then the reconstructed full-precision multiplication results are summed to produce the MAC result. The left shift operations align the partial products according to their significance levels. This approach enables the use of smaller multipliers, such as 2-bit by 2-bit multipliers instead of 8-bit by 8-bit multipliers, while maintaining full precision through the digital combination of partial products for both multiplication and MAC operations.

The bit splicing technique may provide several advantages in terms of ADC resolution requirements, operational speed, and power consumption for both multiplication and MAC operations. The specific benefits depend on the chosen bit-splicing configuration. For a single multiplication with 8-bit operands split into four 2-bit portions, the ADC resolution requirement may be reduced from 16 bits to 2+2=4 bits per partial product. Alternatively, for 8-bit operands split into two 4-bit portions, the ADC resolution requirement may be 4+4=8 bits per partial product, representing a different trade-off between resolution and cycle count. For MAC operations with 8-bit operands, 2-bit splices, and N=4 entries, the ADC resolution requirement may be reduced from 18 bits to 2+2+log₂(4)=6 bits. For 16-bit operands split into four 4-bit portions with N=4 entries, the ADC resolution requirement may be 4+4+log₂(4)=10 bits. This reduction in ADC resolution may simplify the ADC design and reduce the associated power consumption and area requirements for both types of operations.

In terms of operational speed, the original implementation with 8-bit operands for either multiplication or MAC operations may require a time of T_{N}=2⁸·Tᵤ=256Tᵤ, where Tᵤ represents a unit time. With the bit splicing technique using 2-bit slices, the time may be reduced to 4 cycles of T_{N}=2²·Tᵤ=4Tᵤ per cycle, resulting in a total time of 16Tᵤ. This represents approximately a 16× speed improvement compared to the original implementation for both multiplication and MAC operations. For 16-bit operands split into four 4-bit portions, the time may be reduced from 2¹⁶·Tᵤ=65536Tᵤ to 4 cycles of 2⁴·Tᵤ=16Tᵤ per cycle, resulting in a total time of 64Tᵤ, representing approximately a 1024× speed improvement.

Power consumption may also be reduced through the bit splicing technique for both multiplication and MAC operations. The original implementation with 8-bit operands may require a current of I=2⁸·I₀=256I₀. With the bit splicing technique using 2-bit slices, the current may be reduced to I=2²·I₀=4I₀. This represents approximately a 64×reduction in power consumption. For 16-bit operands split into four 4-bit portions, the current may be reduced from 2¹⁶·I₀=65536I₀ to 2⁴·I₀=16I₀, representing approximately a 4096×reduction in power consumption. The ADC power and area may also benefit from the reduced complexity associated with the lower resolution requirement for both types of operations. The choice of bit-splicing configuration may be based on the specific requirements of the application, balancing factors such as cycle count, ADC resolution, power consumption, and hardware complexity.

The bit splicing technique may be applied at multiple levels of a computational hierarchy. At a first level, the technique may be applied to a multiplier circuit for basic partial precision multiplication of two operands, where the multiplier circuit generates all pairwise partial products of the bit-spliced portions and combines them to reconstruct the full-precision multiplication result. At a second level, the technique may be extended to MAC operations, also referred to as vector dot product (VDP) operations, where multiple products are accumulated using a plurality of multiplier circuits with a shared ADC array and digital reconstruction unit that reconstructs individual multiplication results and sums them to produce the MAC result. At a third level, the technique may be further extended to matrix multiplication operations, which may be implemented as repeated MAC operations with parallel MAC circuits. This hierarchical application enables the bit splicing technique to be deployed across a range of computational structures commonly used in signal processing and machine learning applications, from individual multiplications to complex matrix operations.

In various embodiments of the disclosure, a multiplier circuit is described. The multiplier circuit includes an array of current generation units. Each current generation unit of the array of current generation units is configured to generate a current output corresponding to a respective bit-spliced portion of a first set of bit-spliced portions of a first digital operand. The multiplier circuit further includes a signal generation unit configured to generate a set of pulse inputs corresponding to a second set of bit-spliced portions of a second digital operand. The multiplier circuit further includes a switching unit comprising an array of switches respectively coupled to the array of current generation units. The multiplier circuit further includes an integration unit comprising an array of integrator circuits respectively coupled to the array of switches. Applying each pulse input of the set of pulse inputs to a respective switch of the array of switches in a systolic manner gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. The multiplier circuit further includes an ADC array configured to digitize the set of voltage outputs into a set of digitized partial products and a digital reconstruction unit configured to combine the set of digitized partial products based on binary shift and add operations to reconstruct a full-precision multiplication result of the first digital operand and the second digital operand.

In various embodiments of the disclosure, each current generation unit of the array of current generation units comprises a current digital-to-analog converter (DAC), and the current DAC includes a set of binary-weighted current sources and a set of internal switches respectively coupled to the set of binary-weighted current sources.

In various embodiments of the disclosure, the set of internal switches is controlled by bits of the respective bit-spliced portion of the first digital operand.

In various embodiments of the disclosure, the current DAC of each current generation unit of the array of current generation units comprises memory cells configured to store the bits of the respective bit-spliced portion of the first digital operand.

In various embodiments of the disclosure, the signal generation unit comprises a cascaded array of shift registers and an array of pulse width modulation circuits respectively coupled to the cascaded array of shift registers. The cascaded array of shift registers is configured to sequentially shift each bit-spliced portion of the second set of bit-spliced portions to effectuate the systolic manner. Each pulse width modulation circuit of the array of pulse width modulation circuits is configured to receive a bit-spliced portion of the second set of bit-spliced portions from a respective shift register of the cascaded array of shift registers and generate a respective pulse input of the set of pulse inputs based on the received bit-spliced portion.

In various embodiments of the disclosure, each pulse input of the set of pulse inputs has a pulse width corresponding to a value of a respective bit-spliced portion of the second set of bit-spliced portions.

In various embodiments of the disclosure, each integrator circuit of the array of integrator circuits is one of a capacitor-based circuit or an operational amplifier-based circuit.

In various embodiments of the disclosure, the first digital operand and the second digital operand are each N-bit operands, and each bit-spliced portion of the first set of bit-spliced portions and each bit-spliced portion of the second set of bit-spliced portions is a p-bit portion, where p is less than N.

In various embodiments of the disclosure, the first set of bit-spliced portions comprises N/p bit-spliced portions and the second set of bit-spliced portions comprises N/p bit-spliced portions.

In various embodiments of the disclosure, the ADC array comprises an array of analog-to-digital converters configured to digitize the set of voltage outputs into the set of digitized partial products.

In various embodiments of the disclosure, each analog-to-digital converter of the array of analog-to-digital converters has a resolution of 2p bits, where p is a bit width of each bit-spliced portion of the first set of bit-spliced portions and the second set of bit-spliced portions.

In various embodiments of the disclosure, the shift and add operations comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to reconstruct the full-precision multiplication result.

In various embodiments of the disclosure, the first shift amount is 2p bits and the second shift amount is p bits, where p is a bit width of each bit-spliced portion of the first set of bit-spliced portions and the second set of bit-spliced portions.

In various embodiments of the disclosure, the applying of each pulse input of the set of pulse inputs to the respective switch of the array of switches in the systolic manner comprises, in a first cycle of the successive cycles, applying a first pulse input of the set of pulse inputs to a first switch of the array of switches. In a second cycle of the successive cycles, the applying comprises applying the first pulse input to a second switch of the array of switches and applying a second pulse input of the set of pulse inputs to the first switch. The applying further comprises continuing a systolic propagation pattern through remaining cycles of the successive cycles until all pulse inputs of the set of pulse inputs are applied to all switches of the array of switches. The systolic propagation pattern comprises shifting each pulse input to a next switch of the array of switches while introducing a subsequent pulse input to the first switch in each successive cycle.

In various embodiments of the disclosure, the first digital operand represents a weight value of a neural network, and the second digital operand represents an input value for the neural network.

In various embodiments of the disclosure, the signal generation unit is configured to interleave bit-spliced portions from successive instances of the second digital operand such that, during the successive cycles, bit-spliced portions of a current instance of the second digital operand and bit-spliced portions of a previous instance of the second digital operand propagate through the array of switches concurrently. Each current generation unit of the array of current generation units maintains, across the successive cycles, the current output for the respective bit-spliced portion of the first digital operand.

In various embodiments of the disclosure, the digital reconstruction unit comprises a combinational logic circuit configured to perform the shift and add operations.

In various embodiments of the disclosure, the multiplier circuit is configured to operate in a broadcast mode in which a same pulse input of the set of pulse inputs is applied simultaneously to all switches of the array of switches during a single cycle of the successive cycles.

In various embodiments of the disclosure, a multiply-accumulate (MAC) circuit is described. The MAC circuit includes a plurality of multiplier circuits, each multiplier circuit of the plurality of multiplier circuits comprising an array of current generation units. Each current generation unit of the array of current generation units is configured to generate a current output corresponding to a respective bit-spliced portion of a first set of bit-spliced portions of a respective first digital operand. Each multiplier circuit further comprises a signal generation unit configured to generate a set of pulse inputs corresponding to a second set of bit-spliced portions of a respective second digital operand. Each multiplier circuit also comprises a switching unit comprising an array of switches respectively coupled to the array of current generation units, wherein applying each pulse input of the set of pulse inputs to a respective switch of the array of switches gates the current output from a respective current generation unit of the array of current generation units. The MAC circuit further includes a shared array of integrator circuits. Current outputs from corresponding bit positions across the plurality of multiplier circuits are shorted together before integration such that the shared array of integrator circuits accumulates summed currents from the plurality of multiplier circuits. The shared array of integrator circuits is reset between successive cycles such that the shared array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions accumulated across the plurality of multiplier circuits. The MAC circuit further includes an ADC array configured to digitize the set of voltage outputs from the shared array of integrator circuits into a set of digitized partial products, and a digital reconstruction unit configured to combine the set of digitized partial products based on binary shift and add operations to produce a MAC result.

In various embodiments of the disclosure, a method for performing hybrid analog-digital multiplication is described. The method includes generating, by an array of current generation units, a plurality of current outputs. Each current output corresponds to a respective bit-spliced portion of a first set of bit-spliced portions of a first digital operand. The method further includes generating, by a signal generation unit, a set of pulse inputs corresponding to a second set of bit-spliced portions of a second digital operand. The method further includes applying each pulse input of the set of pulse inputs to a respective switch of an array of switches in a systolic manner to gate a current output of the plurality of current outputs from a respective current generation unit of the array of current generation units to a respective integrator circuit of an array of integrator circuits. The method further includes resetting the array of integrator circuits between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. The method further includes digitizing, by an ADC array, the set of voltage outputs into a set of digitized partial products. The method further includes combining, by a digital reconstruction unit, the set of digitized partial products based on shift and add operations to reconstruct a full-precision multiplication result of the first digital operand and the second digital operand.

The following description sets forth exemplary aspects of the present disclosure. It should be recognized, however, that such description is not intended as a limitation on the scope of the present disclosure. Rather, the description also encompasses combinations and modifications to those exemplary aspects described herein.

A detailed description of systems, devices, and methods consistent with embodiments of the present disclosure is provided below. While several embodiments are described, it should be understood that disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

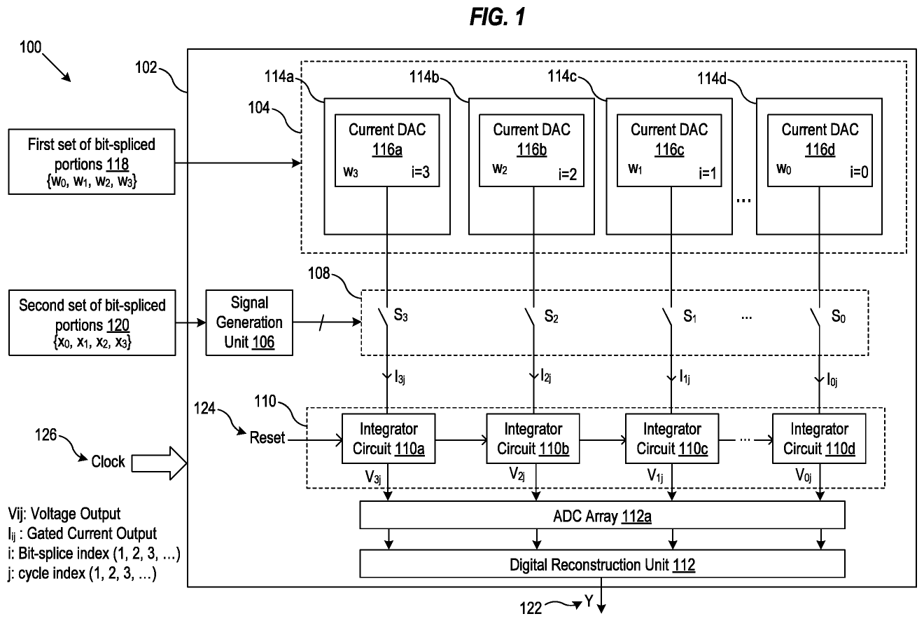

FIG. 1 is a diagram 100 that illustrates a multiplier circuit 102 for partial precision analog computing with bit splicing, in accordance with an embodiment of the disclosure. With reference to FIG. 1, there is shown the diagram 100 of the multiplier circuit 102. The multiplier circuit 102 includes an array of current generation units 104, a signal generation unit 106, a switching unit 108, an integration unit 110, an ADC array 112a, and a digital reconstruction unit 112.

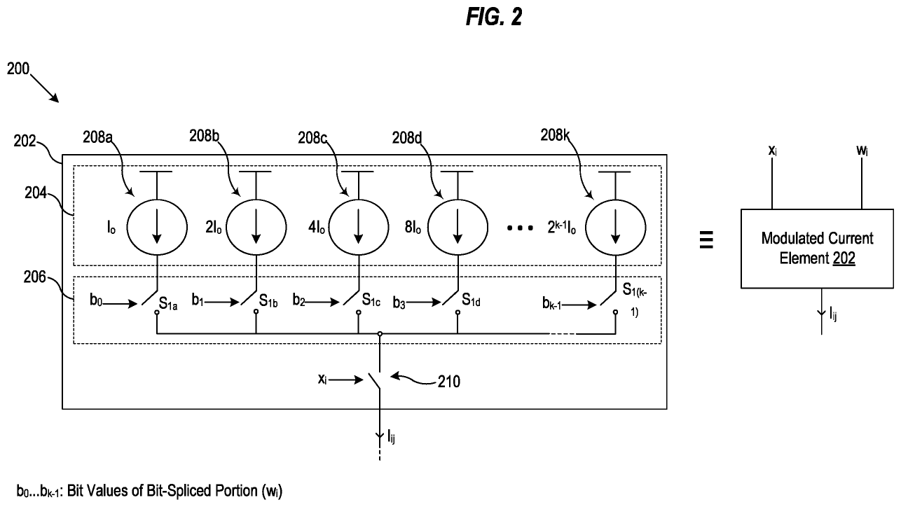

Each current generation unit of the array of current generation units 104 and a respective switch of the switching unit 108 connected to the current generation unit collectively form a modulated current element (MCE) unit, as shown in FIG. 2. The multiplier circuit 102 is configured to perform multiplication operations on digital operands by splitting the digital operands into bit-spliced portions and processing the bit-spliced portions across multiple cycles to generate partial products that are subsequently combined to reconstruct a full-precision multiplication result of a first digital operand and a second digital operand. For example, when multiplying two 8-bit operands, the multiplier circuit 102 may split each 8-bit operand into four 2-bit portions and process the four 2-bit portions across multiple cycles to generate sixteen partial products that are combined through shift and add operations to produce a 16-bit full-precision multiplication result.

Although FIG. 1 depicts a configuration with four MCE units corresponding to four bit-spliced portions, the disclosure is not limited to this specific configuration. The multiplier circuit 102 may be implemented with more or fewer MCE units depending on the bit width of the operands and the desired bit-splicing granularity. For instance, the multiplier circuit 102 may comprise two MCE units for processing 4-bit operands split into two 2-bit portions, eight MCE units for processing 16-bit operands split into eight 2-bit portions, or any other suitable number of MCE units based on the application requirements. In some non-limiting examples, the multiplier circuit 102 may be implemented as part of an analog compute-in-memory (ACIM) system for neural network inference, where the first digital operand represents a weight value and the second digital operand represents an input activation value. In other non-limiting examples, the multiplier circuit 102 may be configured to process operands of varying bit widths, such as 4-bit, 6-bit, or 16-bit operands, by adjusting the number of bit-spliced portions accordingly.

The array of current generation units 104 comprises a current generation unit 114a, a current generation unit 114b, a current generation unit 114c, and a current generation unit 114d. Each current generation unit of the array of current generation units 104 is configured to generate a current output corresponding to a respective bit-spliced portion of a first set of bit-spliced portions 118 of a first digital operand. The first set of bit-spliced portions 118 includes portions w₀, w₁, w₂, and w₃, where each portion represents a subset of bits from the first digital operand. For example, when the first digital operand is an 8-bit value represented as binary value 10110011, the first set of bit-spliced portions 118 may comprise w₀=11 (decimal value 3), w₁=00 (decimal value 0), w₂=11 (decimal value 3), and w₃=10 (decimal value 2), where w₀ represents the least significant 2 bits and w₃ represents the most significant 2 bits. In some embodiments, the first digital operand represents a weight value of a neural network, and the first set of bit-spliced portions 118 represents the weight value divided into smaller bit groups for partial precision processing. In some non-limiting examples, the array of current generation units 104 may comprise two current generation units when processing 4-bit operands split into two 2-bit portions, or eight current generation units when processing 16-bit operands split into eight 2-bit portions. In other non-limiting examples, the array of current generation units 104 may be implemented using CMOS transistor-based current sources, where each current generation unit includes a plurality of matched transistors configured to generate precise binary-weighted currents. In yet other non-limiting examples, the current generation units 114a, 114b, 114c, and 114d may be arranged in a linear array configuration or a matrix configuration depending on the specific implementation requirements of the multiplier circuit 102.

Each current generation unit of the array of current generation units 104 comprises a current digital-to-analog converter (DAC). Specifically, the current generation unit 114a includes a current DAC 116a, the current generation unit 114b includes a current DAC 116b, the current generation unit 114c includes a current DAC 116c, and the current generation unit 114d includes a current DAC 116d. The current DAC 116a corresponds to bit-splice index i=3, the current DAC 116b corresponds to bit-splice index i=2, the current DAC 116c corresponds to bit-splice index i=1, and the current DAC 116d corresponds to bit-splice index i=0. Each current DAC includes a set of binary-weighted current sources and a set of internal switches respectively coupled to the set of binary-weighted current sources. For example, a current DAC configured for 2-bit operation includes a first binary-weighted current source generating a current of magnitude Iₒ and a second binary-weighted current source generating a current of magnitude 2Iₒ, where Iₒ represents a unit current value. The set of internal switches is controlled by bits of the respective bit-spliced portion of the first digital operand, enabling the current DAC to generate a current output proportional to the value represented by the respective bit-spliced portion. For example, when the bit-spliced portion w₀ has a binary value of 11 (decimal value 3), both internal switches are closed, causing the current DAC to output a current of 3Iₒ (Iₒ+2Iₒ). In some embodiments, the current DAC of each current generation unit of the array of current generation units 104 comprises memory cells configured to store the bits of the respective bit-spliced portion of the first digital operand. In some non-limiting examples, the current DAC 116a may be implemented using a segmented architecture where the binary-weighted current sources are realized using unit current cells, such that a 2-bit current DAC comprises three unit current cells (one for the LSB and two for the MSB). In other non-limiting examples, the memory cells may be implemented as static random-access memory (SRAM) cells, dynamic random-access memory (DRAM) cells, or non-volatile memory cells such as flash memory or resistive random-access memory (ReRAM) cells. In yet other non-limiting examples, the unit current value Iₒ may be set to 1 microampere, 10 microamperes, or 100 microamperes depending on the speed and power requirements of the multiplier circuit 102.

With continued reference to FIG. 1, the signal generation unit 106 is configured to generate a set of pulse inputs corresponding to a second set of bit-spliced portions 120 of a second digital operand. The second set of bit-spliced portions 120 includes portions x₀, x₁, x₂, and x₃, where each portion represents a subset of bits from the second digital operand. For example, when the second digital operand is an 8-bit value represented as binary value 11010110, the second set of bit-spliced portions 120 may comprise x₀=10 (decimal value 2), x₁=01 (decimal value 1), x₂=01 (decimal value 1), and x₃=11 (decimal value 3), where x₀ represents the least significant 2 bits and x₃ represents the most significant 2 bits. In some embodiments, the second digital operand represents an input value for a neural network, and the second set of bit-spliced portions 120 represents the input value divided into smaller bit groups for partial precision processing. The signal generation unit 106 generates a set of pulse inputs corresponding to the second set of bit-spliced portions 120, where each pulse input has a pulse width of xᵢ·Tᵤ, with xᵢ representing the decimal value of the respective bit-spliced portion and Tᵤ representing a unit time period. For example, when the bit-spliced portion x₃ has a decimal value of 3, the corresponding pulse input has a pulse width of 3Tᵤ. In some non-limiting examples, the unit time period Tᵤ may be 10 nanoseconds, 100 nanoseconds, or 1 microsecond depending on the operating frequency of the multiplier circuit 102. In other non-limiting examples, the signal generation unit 106 may generate pulse inputs with pulse widths ranging from 0 to 3Tᵤ for 2-bit spliced portions, from 0 to 15Tᵤ for 4-bit spliced portions, or from 0 to 255Tᵤ for 8-bit spliced portions. In yet other non-limiting examples, when the bit-spliced portion x₀ has a decimal value of 2 and Tᵤ=50 nanoseconds, the corresponding pulse input has a pulse width of 100 nanoseconds (2×50 nanoseconds). In some non-limiting examples, the signal generation unit 106 may be implemented using digital counter circuits that count clock cycles to generate pulse widths proportional to the bit-spliced portion values.

In some embodiments, the signal generation unit 106 comprises a cascaded array of shift registers and an array of pulse width modulation circuits respectively coupled to the cascaded array of shift registers. The cascaded array of shift registers is configured to sequentially shift each bit-spliced portion of the second set of bit-spliced portions 120 to effectuate the systolic manner. The cascaded array of shift registers comprises a first shift register, a second shift register, a third shift register, and a fourth shift register connected in series, where the output of each shift register feeds into the input of the next shift register in the cascade. During a first cycle, the bit-spliced portion x₃ is loaded into the first shift register of the cascaded array of shift registers. During a second cycle, the bit-spliced portion x₃ shifts from the first shift register to the second shift register while the bit-spliced portion x₂ is loaded into the first shift register. During a third cycle, the bit-spliced portion x₃ shifts to the third shift register, the bit-spliced portion x₂ shifts to the second shift register, and the bit-spliced portion x₁ is loaded into the first shift register. This sequential shifting pattern continues until all bit-spliced portions have propagated through all shift registers in the cascade, enabling the systolic data flow pattern where each bit-spliced portion is applied to each current generation unit in successive cycles.

Each pulse width modulation circuit of the array of pulse width modulation circuits is configured to receive a bit-spliced portion of the second set of bit-spliced portions 120 from a respective shift register of the cascaded array of shift registers and generate a respective pulse input of the set of pulse inputs based on the received bit-spliced portion. The array of pulse width modulation circuits comprises a first pulse width modulation circuit coupled to the first shift register, a second pulse width modulation circuit coupled to the second shift register, a third pulse width modulation circuit coupled to the third shift register, and a fourth pulse width modulation circuit coupled to the fourth shift register. Each pulse width modulation circuit generates a pulse signal with a pulse width of xᵢ·Tᵤ, where xᵢ is the value stored in its corresponding shift register and Tᵤ is the unit time period. In some non-limiting examples, the cascaded array of shift registers may comprise four 2-bit shift registers connected in series, where each shift register stores a 2-bit spliced portion and shifts its contents to the next shift register on each clock cycle. In other non-limiting examples, the pulse width modulation circuits may be implemented using digital comparators that compare a counter value against the bit-spliced portion value to generate a pulse that transitions from high to low when the counter value equals the bit-spliced portion value. In yet other non-limiting examples, the cascaded array of shift registers may be implemented using D-type flip-flops, where each 2-bit shift register comprises two D-type flip-flops clocked by the clock signal 126. In some non-limiting examples, the signal generation unit 106 may include a parallel load capability that allows all bit-spliced portions x₀, x₁, x₂, and x₃ to be loaded simultaneously into respective shift registers for broadcast mode operation. In other non-limiting examples, the shift registers may include division factors of 2, 2, 4, and 8 respectively from the first to the fourth shift register, indicating scaling relationships between the different bit slice processing paths that correspond to the binary significance of each bit-spliced portion position.

The switching unit 108 comprises an array of switches respectively coupled to the array of current generation units 104. The array of switches includes switches S₃, S₂, S₁, and S₀ respectively coupled to the current generation units 114a, 114b, 114c, and 114d. Applying each pulse input of the set of pulse inputs to a respective switch of the array of switches in a systolic manner gates the current output from a respective current generation unit of the array of current generation units 104 to a respective integrator circuit of the integration unit 110. Specifically, the pulse inputs with pulse widths x₃·Tᵤ, x₂·Tᵤ, x₁·Tᵤ, and x₀·Tᵤ are applied to respective switches S₃, S₂, S₁, and S₀ of the switching unit 108 to gate current outputs I₃ⱼ, I₂ⱼ, I₁ⱼ, and I₀ⱼ from the respective current generation units to the integration unit 110. The notation Iᵢⱼ represents a gated current output where i is the bit-splice index and j is the cycle index. For example, I₃₁ represents the gated current output from the current generation unit 114a (bit-splice index i=3) during cycle j=1. In some non-limiting examples, the array of switches may be implemented using NMOS transistors, PMOS transistors, or transmission gates, where each switch is controlled by a respective pulse input signal. In other non-limiting examples, when the pulse input applied to switch S₃ has a pulse width of 3Tᵤ (corresponding to x₃=3) and the current generation unit 114a outputs a current of 2Iₒ, the gated current output I₃₁ flows at a magnitude of 2Iₒ for the duration of 3Tᵤ. In some non-limiting examples, the systolic manner of applying pulse inputs may involve applying the pulse input with width x₃·Tᵤ to switch S₃ during cycle 1, applying the pulse input with width x₃·Tᵤ to switch S₂ and the pulse input with width x₂·Tᵤ to switch S₃ during cycle 2, and continuing this pattern until all pulse inputs have propagated through all switches.

As further shown in FIG. 1, the integration unit 110 comprises an array of integrator circuits respectively coupled to the array of switches. The array of integrator circuits includes an integrator circuit 110a, an integrator circuit 110b, an integrator circuit 110c, and an integrator circuit 110d. The integrator circuit 110a produces a voltage output V₃ⱼ, the integrator circuit 110b produces a voltage output V₂ⱼ, the integrator circuit 110c produces a voltage output V₁ⱼ, and the integrator circuit 110d produces a voltage output V₀ⱼ. The notation Vᵢⱼ represents a voltage output where i is the bit-splice index and j is the cycle index. For example, V₃₁ represents the voltage output from the integrator circuit 110a (bit-splice index i=3) during cycle j=1. Each integrator circuit of the array of integrator circuits is one of a capacitor-based circuit or an operational amplifier-based circuit configured to accumulate charge from the gated current output over the duration of the corresponding pulse input. For example, when the integrator circuit 110a is a capacitor-based circuit with capacitance C, and the gated current output I₃₁ has a magnitude of 3Iₒ flowing for a pulse duration of 2Tᵤ, the voltage output V₃₁ equals (3Iₒ ×2Tᵤ)/C=6IₒTᵤ/C, representing the partial product of w₃ and x₃. In some non-limiting examples, the integrator circuit 110a may be implemented as a simple capacitor with capacitance C=1 picofarad connected between the switch output and ground, where the voltage across the capacitor increases as current flows into it. In other non-limiting examples, the integrator circuit 110b may be implemented as an operational amplifier-based integrator comprising an operational amplifier with a feedback capacitor C_{f}=500 femtofarads connected between the output and the inverting input, providing improved linearity and output impedance compared to a simple capacitor-based circuit. In some non-limiting examples, the integrator circuits 110a, 110b, 110c, and 110d may share a common reference voltage to ensure consistent baseline levels across all voltage outputs.

The integration unit 110 receives a reset signal 124 that resets the array of integrator circuits between successive cycles. The reset signal 124 discharges any accumulated charge on the integrator circuits to establish a known initial state prior to each cycle of operation. For example, when the integrator circuits are capacitor-based circuits, the reset signal 124 closes reset switches that discharge the capacitors to ground potential before each new cycle begins. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions 118 and the second set of bit-spliced portions 120. For example, when the first set of bit-spliced portions 118 comprises four 2-bit portions (w₀, w₁, w₂, w₃) and the second set of bit-spliced portions 120 comprises four 2-bit portions (x₀, x₁, x₂, x₃), the set of voltage outputs comprises sixteen partial products corresponding to all pairwise combinations: w₀×x₀, w₀×x₁, w₀×x₂, w₀×x₃, w₁×x₀, w₁×x₁, w₁×x₂, w₁×x₃, w₂×x₀, w₂×x₁, w₂×x₂, w₂×x₃, w₃×x₀, w₃×x₁, w₃×x₂, and w₃×x₃. In some non-limiting examples, the reset signal 124 may be a digital pulse that activates NMOS reset transistors connected in parallel with each integrator capacitor. In other non-limiting examples, the reset signal 124 may be generated by the clock signal 126 through a delay circuit that produces a reset pulse at the beginning of each clock cycle. In yet other non-limiting examples, when processing 8-bit operands split into four 2-bit portions using systolic data flow, the multiplier circuit 102 may require seven cycles to generate all sixteen partial products, with four partial products generated per cycle during cycles 1 through 4 and progressively fewer partial products during cycles 5 through 7. In some non-limiting examples, the reset signal 124 may have an active-low polarity, where the integrator circuits are reset when the reset signal 124 is at logic low level and accumulate charge when the reset signal 124 is at logic high level.

A clock signal 126 is provided to coordinate the timing of operations within the multiplier circuit 102. The clock signal 126 synchronizes the operation of the signal generation unit 106, the switching unit 108, the integration unit 110, the ADC array 112a, and the digital reconstruction unit 112 to ensure proper sequencing of the systolic data flow and the generation of partial products across successive cycles. The clock signal 126 controls the shifting of bit-spliced portions through the cascaded array of shift registers in the signal generation unit 106, where each rising edge of the clock signal 126 causes each shift register to transfer its stored bit-spliced portion to the next shift register in the cascade while simultaneously loading a new bit-spliced portion into the first shift register. For example, the clock signal 126 may have a period of 4Tᵤ when processing 2-bit spliced portions, where each clock cycle allows sufficient time for the pulse width modulation circuits to generate pulse inputs with widths ranging from 0 to 3Tᵤ. In some non-limiting examples, the clock signal 126 may be generated by an on-chip phase-locked loop (PLL) or provided by an external clock source. In yet other non-limiting examples, the clock signal 126 may have a duty cycle of 50%, with the rising edge triggering the shift register operations and the falling edge triggering generation of the reset signal 124. In some non-limiting examples, when processing 8-bit operands split into four 2-bit portions with a clock frequency of 100 MHz, the multiplier circuit 102 may complete a full multiplication operation in 70 nanoseconds (7 cycles ×10 nanoseconds per cycle) using systolic data flow, compared to 2560 nanoseconds (256Tᵤ ×10 nanoseconds) for a conventional full-precision implementation.

With continued reference to FIG. 1, the ADC array 112a is coupled to receive the voltage outputs V₃ⱼ, V₂ⱼ, V₁ⱼ, and V₀ⱼ from the integration unit 110. The ADC array 112a is configured to digitize the set of voltage outputs into a set of digitized partial products. In some embodiments, the ADC array 112a comprises an array of analog-to-digital converters configured to digitize the set of voltage outputs into the set of digitized partial products. Each analog-to-digital converter of the array of analog-to-digital converters has a resolution of 2p bits, where p is a bit width of each bit-spliced portion of the first set of bit-spliced portions 118 and the second set of bit-spliced portions 120. For example, when each bit-spliced portion is 2 bits wide (p=2), each analog-to-digital converter has a resolution of 4 bits (2×2=4 bits), which is sufficient to represent the maximum partial product value of 3×3=9 (requiring 4 bits). In contrast, a conventional implementation processing full 8-bit operands would require an analog-to-digital converter with 18-bit resolution (8+8+log₂(4)=18 bits for 4 accumulations), demonstrating a significant reduction in analog-to-digital converter complexity through the bit splicing technique. In some non-limiting examples, the array of analog-to-digital converters may comprise four successive approximation register (SAR) analog-to-digital converters. In other non-limiting examples, the array of analog-to-digital converters may comprise flash analog-to-digital converters for higher speed operation or sigma-delta analog-to-digital converters for higher resolution applications. In yet other non-limiting examples, when processing 8-bit operands split into four 2-bit portions, the ADC array 112a may include four 6-bit analog-to-digital converters (2+2+log₂(4)=6 bits) when accumulating partial products from four MAC operations.

The digital reconstruction unit 112 is further configured to combine the set of digitized partial products based on binary shift and add operations to reconstruct a full-precision multiplication result 122, denoted as Y, of the first digital operand and the second digital operand. The shift and add operations comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to reconstruct the full-precision multiplication result 122. In some embodiments, the first shift amount is 2p bits and the second shift amount is p bits, wherein p is a bit width of each bit-spliced portion of the first set of bit-spliced portions 118 and the second set of bit-spliced portions 120. For example, when p=2 bits, the partial product w₃×x₃ (representing the MSB×MSB product) is left-shifted by 4 bits (2p=4), the partial products w₃×x₂, w₃×x₁, w₂×x₃, and w₁×x₃ are left-shifted by 2 bits (p=2), and the partial product w₀×x₀ (representing the LSB×LSB product) is not shifted. The full-precision multiplication result 122 is computed as: Result=(w₀×x₀)+((w₀×x₁+w₁×x₀) <<p)+((w₀×x₂+w₁×x₁+w₂×x₀)<<2p)+ . . .+((w₃×x₃)<<6p), where <<denotes left shift operation. In some embodiments, the digital reconstruction unit 112 comprises a combinational logic circuit configured to perform the shift and add operations. In some non-limiting examples, when multiplying X=11 (binary 1011, with w₀=11, w₁=10) by Y=13 (binary 1101, with x₀=01, x₁=11), the partial products are BD=w₀×x₀=3×1=3, AD=w₁×x₀=2×1=2, BC=w₀×x₁=3×3=9, and AC=w₁×x₁=2×3=6, and the full-precision result is computed as 3+(2 +9)<<2+6<<4=3+44+96=143, which equals 11×13. In other non-limiting examples, the combinational logic circuit may be implemented using a tree of carry-save adders followed by a final carry-propagate adder to efficiently sum the shifted partial products. In yet other non-limiting examples, the digital reconstruction unit 112 may include pipeline registers between the ADC array 112a and the shift-and-add logic to improve throughput. In some non-limiting examples, the shift operations may be implemented using hardwired connections that route the digitized partial product bits to appropriate bit positions in an accumulator register, eliminating the need for barrel shifters.

FIG. 2 is a diagram 200 that illustrates a modulated current element 202 for partial precision analog computing operations, in accordance with an embodiment of the disclosure. FIG. 2 is explained in conjunction with elements from FIG. 1. With reference to FIG. 2, there is shown the diagram 200 of the modulated current element 202. The modulated current element 202 receives two inputs, denoted as xᵢ and wᵢ, and produces a current output Iᵢⱼ. The modulated current element 202 may be implemented within each current generation unit of the array of current generation units 104 described with reference to FIG. 1. In such implementations, the modulated current element 202 is configured to generate a current output corresponding to a respective bit-spliced portion of a first set of bit-spliced portions of a first digital operand (represented by wᵢ), and the current output is gated based on a pulse input corresponding to a respective bit-spliced portion of a second set of bit-spliced portions of a second digital operand (represented by xᵢ).

The modulated current element 202 comprises a set of binary-weighted current sources 204 and a set of internal switches 206 respectively coupled to the set of binary-weighted current sources 204. The set of binary-weighted current sources 204 includes a first binary-weighted current source 208a configured to generate a current of magnitude Iₒ, a second binary-weighted current source 208b configured to generate a current of magnitude 2Iₒ, a third binary-weighted current source 208c configured to generate a current of magnitude 4Iₒ, a fourth binary-weighted current source 208d configured to generate a current of magnitude 8Iₒ, and a k-th binary-weighted current source 208k configured to generate a current of magnitude 2^{(k-1)}·Iₒ. The binary-weighted current sources are arranged to provide exponentially scaled current values corresponding to bit positions of a digital operand. For example, when the modulated current element 202 is configured for 4-bit operation, the set of binary-weighted current sources 204 includes four current sources generating currents of Iₒ, 2Iₒ, 4Iₒ, and 8Iₒ, enabling representation of values from 0 to 15 in the current domain.

In some non-limiting examples, the first binary-weighted current source 208a may be implemented using a single NMOS transistor biased in saturation region with a gate voltage set by a bias circuit to produce the unit current Iₒ. In other non-limiting examples, the second binary-weighted current source 208b may be implemented using two matched NMOS transistors connected in parallel, each producing Iₒ, to generate the current 2Iₒ with improved matching characteristics. The set of binary-weighted current sources 204 may be implemented using unit current cells, where each binary-weighted current source comprises a number of unit current cells equal to its binary weight. For example, the first binary-weighted current source 208a comprises one unit current cell, the second binary-weighted current source 208b comprises two unit current cells, the third binary-weighted current source 208c comprises four unit current cells, and the fourth binary-weighted current source 208d comprises eight unit current cells. This unit cell approach provides improved matching characteristics across the binary-weighted current sources. For an N-bit current DAC implementation, the total number of unit current cells is given by the summation Σ(k=0 to N−1) 2^{k}, which equals 2^{N}−1 unit cells. For example, an 8-bit current DAC implementation consumes 255·Aᵤ area, where Aᵤ represents the unit area of a unit element that produces the unit current Iᵤ.

With continued reference to FIG. 2, the set of internal switches 206 is controlled by bits of the respective bit-spliced portion of the first digital operand. Specifically, the set of internal switches 206 comprises individual switches controlled by bit values b₀, b₁, b₂, b₃ through b₍ₖ₋₁₎, which represent bits of the respective bit-spliced portion of the input wᵢ. Each internal switch of the set of internal switches 206 is coupled between a respective binary-weighted current source and a common output node. A switch S₁ₐ is associated with the first binary-weighted current source 208a and controlled by bit b₀. A switch S_{1b} is associated with the second binary-weighted current source 208b and controlled by bit b₁. A switch S_{1c} is associated with the third binary-weighted current source 208c and controlled by bit b₂. A switch S_{1d} is associated with the fourth binary-weighted current source 208d and controlled by bit b₃. A switch S₁₍ₖ₋₁₎is associated with the k-th binary-weighted current source 208k and controlled by bit b₍ₖ₋₁₎. For example, when the respective bit-spliced portion wᵢ has a binary value of 1011 (decimal value 11), the bit values are b₀=1, b₁=1, b₂=0, and b₃=1, causing switches S₁ₐ, S_{1b}, and S_{1d} to close while switch S_{1c} remains open, resulting in a combined current of Iₒ+2Iₒ+8Iₒ=11Iₒ at the common output node. In some non-limiting examples, each internal switch of the set of internal switches 206 may be implemented using an NMOS pass transistor. In other non-limiting examples, the modulated current element 202 comprises memory cells configured to store the bits of the respective bit-spliced portion of the first digital operand, where the memory cells may be implemented as SRAM cells or latches that maintain the bit values across multiple cycles of operation. In yet other non-limiting examples, when the modulated current element 202 is configured for 2-bit operation as described with reference to FIG. 1, the set of internal switches 206 comprises two switches controlled by bit values b₀ and b₁, enabling representation of values from 0 to 3 in the current domain.

A switch 210 is positioned at the output of the modulated current element 202 and receives the input xᵢ, which corresponds to a pulse input of the set of pulse inputs generated by the signal generation unit 106. The switch 210 gates the current output from the set of binary-weighted current sources 204 based on the pulse input xᵢ to produce the current output Iᵢⱼ. The switch 210 is coupled between the common output node of the set of internal switches 206 and an output terminal of the modulated current element 202. Applying the pulse input xᵢ to the switch 210 gates the current output from the modulated current element 202 to a respective integrator circuit of the array of integrator circuits. When the switch 210 is activated by the pulse input xᵢ and a corresponding internal switch of the set of internal switches 206 is closed based on its respective bit value, the weighted current flows through to contribute to the current output Iᵢⱼ. The current output Iᵢⱼ represents the product of the inputs xᵢ and wᵢ, where the multiplication is performed in the analog domain through the interaction of the pulse-controlled switch such as the switch 210 and the binary-weighted current sources controlled by the bits of the respective bit-spliced portion wᵢ. The switch 210 implements a logical AND operation in the circuit, where the weighted current flows to the output only when two conditions are simultaneously met: the pulse input xᵢ (which has a pulse width corresponding to a value of a respective bit-spliced portion of the second set of bit-spliced portions) is high and the corresponding bit value of wᵢ is also high. When either the pulse input xᵢ is low or the bit value is 0, no current flows through the corresponding path to the output. For example, when the pulse input xᵢ has a pulse width of 3Tᵤ (representing a value of 3) and the respective bit-spliced portion wᵢ has a value of 2 (binary 10, with b₀=0 and b₁=1), the switch 210 is closed for a duration of 3Tᵤ, and during this time, only the current 2Iₒ from the second binary-weighted current source 208b flows to the output because only switch S_{1b} is closed. The resulting charge accumulated on an integrator circuit of the array of integrator circuits coupled to the output of the modulated current element 202 is 2Iₒ×3Tᵤ=6IₒTᵤ, representing the partial product 2×3=6. This partial product corresponds to one of the pairwise partial products of the first set of bit-spliced portions and the second set of bit-spliced portions. In some non-limiting examples, the switch 210 may be implemented using a transmission gate comprising a parallel combination of an NMOS transistor and a PMOS transistor to provide rail-to-rail switching capability. In other non-limiting examples, when the pulse input xᵢ has a pulse width of 0 (representing a value of 0), the switch 210 remains open for the entire cycle, and no current flows to the output regardless of the bits of the respective bit-spliced portion wᵢ, correctly producing a partial product of 0. The modulated current element 202 thus implements a current-mode digital-to-analog converter (DAC) where the first digital operand wᵢ is converted to a proportional current magnitude, and the second digital operand xᵢ is converted to a proportional pulse width, such that the product of the two operands is represented by the total charge transferred to the integrator circuit during the pulse duration.

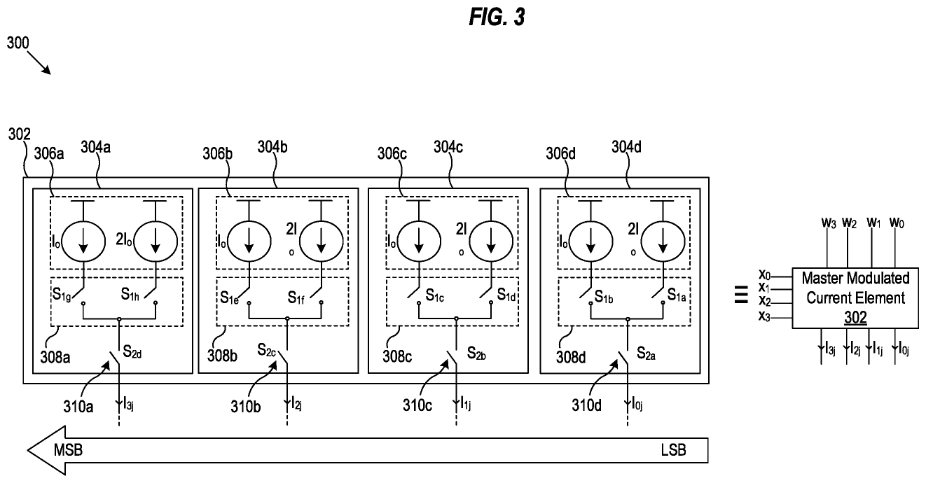

FIG. 3 is a diagram 300 that illustrates a master modulated current element 302 comprising multiple modulated current elements, in accordance with an embodiment of the disclosure. FIG. 3 is explained in conjunction with elements from FIG. 1 and FIG. 2. With reference to FIG. 3, there is shown the diagram 300 of the master modulated current element 302. The master modulated current element 302 is configured for partial precision analog computing with bit splicing and may be implemented within the multiplier circuit 102 described with reference to FIG. 1 and the modulated current element described in FIG. 2.

The master modulated current element 302 comprises an array of modulated current elements, where each modulated current element of the array of modulated current elements is structurally similar to the modulated current element 202 described with reference to FIG. 2. Specifically, the master modulated current element 302 is composed of an array of current generation units arranged in parallel configuration, wherein each current generation unit of the array of current generation units corresponds to an instance of the modulated current element 202 and is configured to generate a current output corresponding to a respective bit-spliced portion of a first set of bit-spliced portions of a first digital operand. In some non-limiting examples, the master modulated current element 302 may be fabricated as a single integrated circuit block that receives bit-spliced portions of weight values and generates current outputs corresponding to partial products when gated by pulse inputs representing bit-spliced portions of a second digital operand.

The master modulated current element 302 comprises a modulated current element 304a, a modulated current element 304b, a modulated current element 304c, and a modulated current element 304d, which collectively form the array of current generation units. Each of the modulated current elements 304a, 304b, 304c, and 304d is an instance of the modulated current element 202 described with reference to FIG. 2, comprising a respective set of binary-weighted current sources, a respective set of internal switches, and a respective output switch as described in the modulated current element 202. The modulated current element 304a corresponds to the most significant bit (MSB) position while the modulated current element 304d corresponds to the least significant bit (LSB) position. Each current generation unit of the array of current generation units, including the modulated current elements 304a, 304b, 304c, and 304d, is configured to generate a current output corresponding to a respective bit-spliced portion of the first set of bit-spliced portions of the first digital operand. For example, when the first digital operand and the second digital operand are each N-bit operand, each bit-spliced portion of the first set of bit-spliced portions and each bit-spliced portion of the second set of bit-spliced portions is a p-bit portion, where p is less than N and the first set of bit-spliced portions comprises N/p bit-spliced portions. In this configuration, the modulated current element 304a processes the most significant p-bit portion, the modulated current element 304b processes the next p-bit portion, the modulated current element 304c processes the subsequent p-bit portion, and the modulated current element 304d processes the least significant p-bit portion. In a specific example where the first digital operand is an 8-bit value split into four 2-bit portions, the modulated current element 304 a processes bits 7-6, the modulated current element 304b processes bits 5-4, the modulated current element 304c processes bits 3-2, and the modulated current element 304d processes bits 1-0. In some non-limiting examples, the modulated current elements 304a, 304b, 304c, and 304d may be identical in structure to the modulated current element 202, differing only in the bit-spliced portion values stored within their respective memory cells.

Each current generation unit of the array of current generation units comprises a current digital-to-analog converter (DAC), and the current DAC includes a set of binary-weighted current sources and a set of internal switches respectively coupled to the set of binary-weighted current sources, as described with reference to the set of binary-weighted current sources 204 and the set of internal switches 206 of the modulated current element 202 in FIG. 2. Specifically, the modulated current element 304a includes a set of binary-weighted current sources 306a, the modulated current element 304b includes a set of binary-weighted current sources 306b, the modulated current element 304c includes a set of binary-weighted current sources 306c, and the modulated current element 304d includes a set of binary-weighted current sources 306d. The set of binary-weighted current sources 306a comprises a first current source generating a current Iₒ and a second current source generating a current 2Iₒ. Similarly, the set of binary-weighted current sources 306b, the set of binary-weighted current sources 306c, and the set of binary-weighted current sources 306d each comprise current sources generating currents Iₒ and 2Iₒ respectively. The binary weighting of the current sources enables representation of multi-bit values within each bit-spliced portion. For example, when a 2-bit spliced portion has a value of 3 (binary 11), both current sources within the respective set of binary-weighted current sources are activated, producing a combined current of Iₒ+2Iₒ=3Iₒ. The four sets of binary-weighted current sources 306a, 306b, 306c, and 306d are arranged in a parallel configuration within the master modulated current element 302, with each set independently controllable by its respective bit-spliced portion of the first digital operand.

With continued reference to FIG. 3, the set of internal switches of each current generation unit is controlled by bits of the respective bit-spliced portion of the first digital operand. The modulated current element 304a includes a set of internal switches 308a, the modulated current element 304b includes a set of internal switches 308b, the modulated current element 304c includes a set of internal switches 308c, and the modulated current element 304d includes a set of internal switches 308d. Each set of internal switches 308a, 308b, 308c, and 308d corresponds to the set of internal switches 206 described with reference to the modulated current element 202 in FIG. 2. The set of internal switches 308a comprises switches labeled S_{1g} and S₁ₕ that control the flow of current from the respective binary-weighted current sources in the set of binary-weighted current sources 306a. The set of internal switches 308b comprises switches labeled S₁ₑ and S_{1f} that control the flow of current from the respective binary-weighted current sources in the set of binary-weighted current sources 306b. The set of internal switches 308c comprises switches labeled S_{1c} and S_{1d} that control the flow of current from the respective binary-weighted current sources in the set of binary-weighted current sources 306c. The set of internal switches 308d comprises switches labeled S₁ₐ and S_{1b} that control the flow of current from the respective binary-weighted current sources in the set of binary-weighted current sources 306d. Each set of internal switches is coupled between the respective binary-weighted current sources and a common output node within each modulated current element, enabling selective activation of current sources based on the bit values of the respective bit-spliced portion.

As indicated in the diagram 300, the first digital operand represents a weight value of a neural network, and the second digital operand represents an input value for the neural network. The first set of bit-spliced portions comprises weight values W₃, W₂, W₁, and W₀. The weight value W₃ controls the set of internal switches 308a, the weight value W₂ controls the set of internal switches 308b, the weight value W₁ controls the set of internal switches 308c, and the weight value W₀ controls the set of internal switches 308d. For example, when the weight value W₃ has a binary value of 10 (decimal value 2), the switch S_{1g} is open (controlled by bit 0 of W₃) and the switch S₁ₕ is closed (controlled by bit 1 of W₃), causing only the current 2Iₒ from the set of binary-weighted current sources 306a to flow to the output of the modulated current element 304a. In some non-limiting examples, the current DAC of each current generation unit of the array of current generation units comprises memory cells configured to store the bits of the respective bit-spliced portion of the first digital operand, allowing the weight values to remain static across multiple cycles while input values change. The weight values W₃, W₂, W₁, and W₀ are arranged from the MSB position to the LSB position, corresponding to the modulated current elements 304a, 304b, 304c, and 304d respectively.

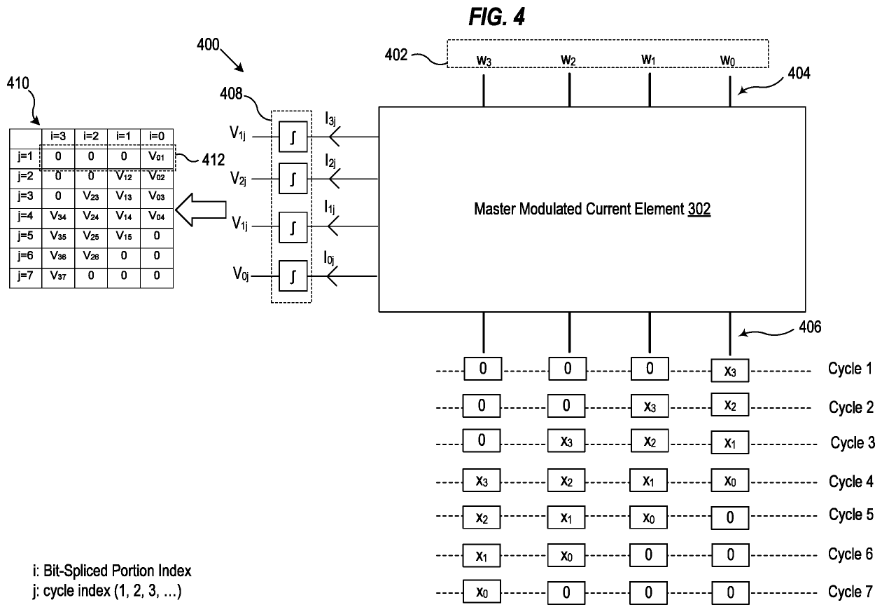

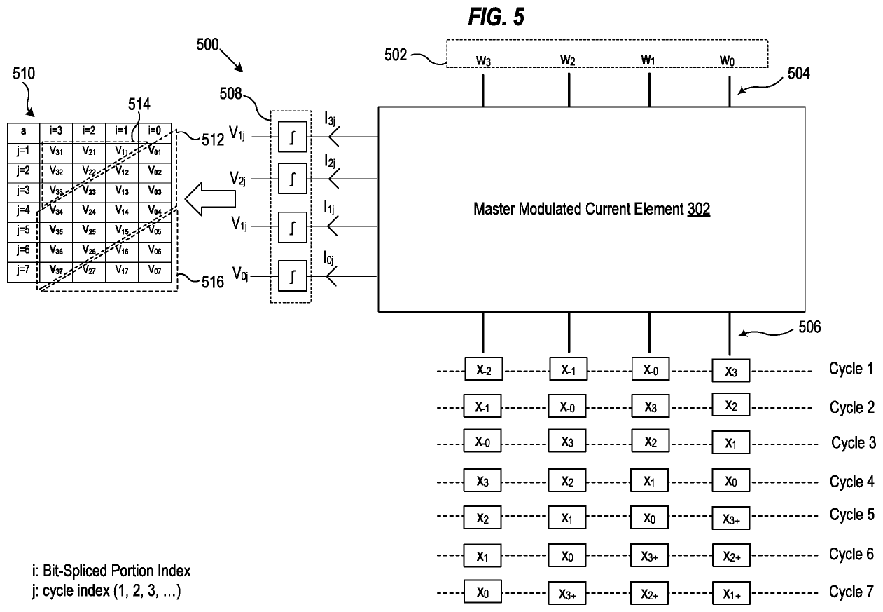

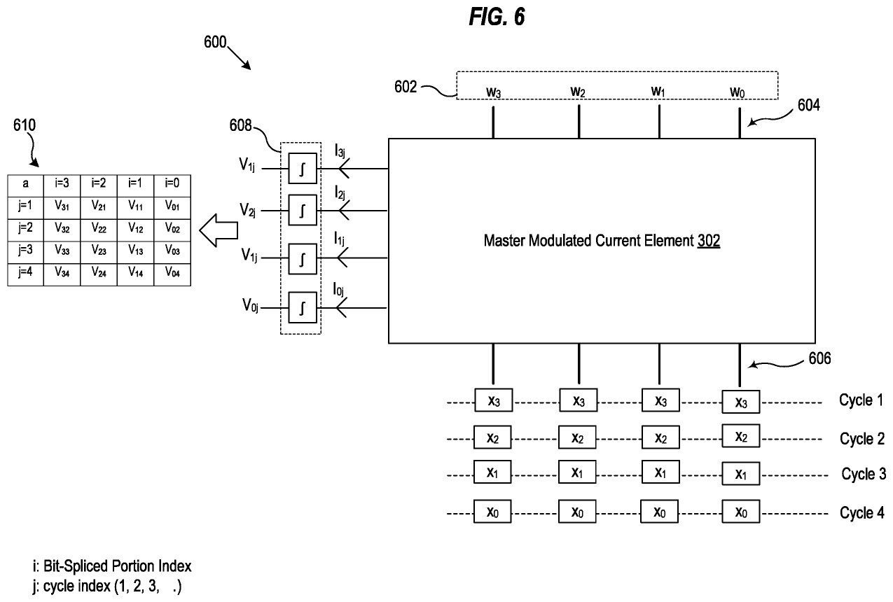

The master modulated current element 302 further comprises a switching unit comprising an array of switches respectively coupled to the array of current generation units. The array of switches includes a switch 310a, a switch 310b, a switch 310c, and a switch 310d. Each of the switches 310a, 310b, 310c, and 310d corresponds to the switch 210 described with reference to the modulated current element 202 in FIG. 2, where each switch gates the current output from its respective modulated current element based on a pulse input. The switch 310a is labeled S_{2d} and is coupled to the output of the modulated current element 304a to control the current output I₃ⱼ. The switch 310b is labeled S_{2c} and is coupled to the output of the modulated current element 304b to control the current output I₂ⱼ. The switch 310c is labeled S_{2b} and is coupled to the output of the modulated current element 304c to control the current output I₁ⱼ. The switch 310d is labeled S₂ₐ and is coupled to the output of the modulated current element 304d to control the current output I₀ⱼ. The signal generation unit 106 is configured to generate a set of pulse inputs corresponding to a second set of bit-spliced portions of the second digital operand, where the second set of bit-spliced portions comprises portions X₃, X₂, X₁, and X₀. The pulse inputs corresponding to X₃, X₂, X₁, and X₀ are applied to the switches 310a, 310b, 310c, and 310d respectively. The pulse inputs may be applied in different operational modes depending on the configuration of the master modulated current element 302. In a systolic manner, as described with reference to FIG. 4 and FIG. 5, each pulse input of the set of pulse inputs propagates through the array of switches across successive cycles, where a first pulse input is applied to a first switch during a first cycle, shifts to a second switch during a second cycle while a second pulse input is introduced to the first switch, and continues this sequential shifting pattern until all pulse inputs have been applied to all switches. Alternatively, in a broadcast mode, as described with reference to FIG. 6, a same pulse input of the set of pulse inputs is applied simultaneously to all switches of the array of switches during a single cycle of the successive cycles. Applying each pulse input of the set of pulse inputs to a respective switch of the array of switches gates the current output from a respective current generation unit of the array of current generation units to a respective integrator circuit of an array of integrator circuits. For example, when the pulse input corresponding to X₃ is applied to the switch 310a, the switch 310a closes for a duration corresponding to the value of X₃, allowing the current from the modulated current element 304a to flow to the integrator circuit 110a. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. The current outputs I₃ⱼ, I₂ⱼ, I₁ⱼ, and I₀ⱼ represent partial products that are subsequently integrated and digitized by the ADC array 112a. The digital reconstruction unit 112 is configured to combine the set of digitized partial products based on binary shift and add operations to reconstruct a full-precision multiplication result of the first digital operand and the second digital operand. In some non-limiting examples, when the weight value W₃=2 and the bit-spliced portion X₃=3, the switch 310a is closed for a duration of 3Tᵤ, and the current I₃ⱼ=2Iₒ flows to the integrator circuit 110a, producing a voltage output proportional to the partial product 2×3=6. The notation Iᵢⱼ represents a gated current output where i is the bit-splice index corresponding to the position of the modulated current element (i=3 for the MSB position and i=0 for the LSB position) and j is the cycle index.

FIG. 4 is a block diagram 400 that illustrates the master modulated current element 302 configured for systolic data flow operation, in accordance with an embodiment of the disclosure. FIG. 4 is explained in conjunction with elements from FIG. 1, FIG. 2, and FIG. 3. With reference to FIG. 4, there is shown the block diagram 400. The block diagram 400 depicts the master modulated current element 302 receiving a first set of bit-spliced portions 402 comprising weight values w₃, w₂, w₁, and w₀ at internal switch input terminals 404. The first set of bit-spliced portions 402 represents bit-spliced portions of a first digital operand stored within the master modulated current element 302. The master modulated current element 302 also receives input signals at switch array input terminals 406, where a set of pulse inputs corresponding to a second set of bit-spliced portions of a second digital operand are applied to gate current outputs from the respective modulated current elements within the master modulated current element 302. In some non-limiting examples, the internal switch input terminals 404 may be coupled to memory cells configured to store the bits of the respective bit-spliced portion of the first digital operand across multiple cycles of operation, while the switch array input terminals 406 receive time-varying pulse inputs that propagate through the master modulated current element 302 in a systolic manner.

With continued reference to FIG. 4, the block diagram 400 includes an array of integrator circuits 408 coupled to the master modulated current element 302. The array of integrator circuits 408 comprises four integrator circuits respectively coupled to an array of switches within the master modulated current element 302. Each integrator circuit of the array of integrator circuits 408 receives a current output from a respective current generation unit of an array of current generation units, where the current outputs are designated as I₃ⱼ, I₂ⱼ, I₁ⱼ, and I₀ⱼ, and j represents the cycle index. Each integrator circuit of the array of integrator circuits 408 accumulates the gated current output over time to produce voltage outputs. The array of integrator circuits 408 is reset between successive cycles such that the array of integrator circuits 408 produces, after each cycle of the successive cycles, a subset of voltage outputs 412 of a set of voltage outputs 410. In some non-limiting examples, each integrator circuit of the array of integrator circuits 408 is a capacitor-based circuit where each integrator circuit comprises a capacitor that accumulates charge from the gated current output during each cycle and is discharged by a reset signal prior to the next cycle. In other non-limiting examples, each integrator circuit of the array of integrator circuits 408 is an operational amplifier-based circuit that provides improved linearity and output impedance characteristics.

As further shown in FIG. 4, the set of voltage outputs 410 is organized in a matrix format showing the relationship between bit-spliced portion indices and cycle indices. The set of voltage outputs 410 corresponds to all pairwise partial products of the first set of bit-spliced portions 402 and the second set of bit-spliced portions of the second digital operand. The set of voltage outputs 410 is represented as a table with columns corresponding to bit-spliced portion index i ranging from 0 to 3 and rows corresponding to cycle index j ranging from 1 to 7. The table entries show voltage values Vᵢⱼ where non-zero values appear in a diagonal pattern across cycles, reflecting the systolic propagation of bit-spliced portions through the master modulated current element 302. For cycle j equals 1, only V₀₁ is non-zero, corresponding to the partial product generated when a first pulse input of the set of pulse inputs enters the array of switches. For cycle j equals 2, V₁₂ and V₀₂ are non-zero, corresponding to partial products generated as the first pulse input is applied to a second switch of the array of switches and a second pulse input of the set of pulse inputs is applied to a first switch. This diagonal pattern continues through cycle j equals 7, where only V₃₇ is non-zero, corresponding to the final partial product generated as the last pulse input exits the array of switches.

The block diagram 400 further illustrates the subset of voltage outputs 412 corresponding to the outputs produced during each cycle of the successive cycles. The lower portion of the block diagram 400 shows the systolic propagation of input values x₃, x₂, x₁, and x₀ across cycles 1 through 7, where zeros fill positions before and after the active input values propagate through the master modulated current element 302. In a first cycle of the successive cycles, only x₃ is present at the rightmost position corresponding to bit-splice index i=0, with zeros in the remaining three positions. In a second cycle of the successive cycles, x₃ shifts to the next position corresponding to bit-splice index i=1 while x₂ enters the rightmost position. In cycle 3, x₃ shifts to bit-splice index i=2, x₂ shifts to bit-splice index i=1, and x₁ enters the rightmost position. In cycle 4, all four input values x₃, x₂, x₁, and x₀ are simultaneously present across the four positions, with x₃ at the leftmost position corresponding to bit-splice index i=3, x₂ at bit-splice index i=2, x₁ at bit-splice index i=1, and x₀ at the rightmost position corresponding to bit-splice index i=0. In cycle 5, x₃ exits the array, x₂ shifts to the leftmost position, x₁ shifts to bit-splice index i=2, x₀ shifts to bit-splice index i=1, and a zero enters the rightmost position. In cycle 6, x₂ exits the array, x₁ shifts to the leftmost position, x₀ shifts to bit-splice index i=2, and zeros occupy the remaining positions. By cycle 7, only x₀ remains at the leftmost position with zeros in the remaining positions.

The systolic data flow operation depicted in the block diagram 400 enables sequential processing of bit-spliced portions through the array of current generation units within the master modulated current element 302. The applying of each pulse input of the set of pulse inputs to a respective switch of the array of switches in the systolic manner comprises, in a first cycle of the successive cycles, applying a first pulse input of the set of pulse inputs to a first switch of the array of switches. In a second cycle of the successive cycles, the applying comprises applying the first pulse input to a second switch of the array of switches and applying a second pulse input of the set of pulse inputs to the first switch. The systolic propagation pattern comprises shifting each pulse input to a next switch of the array of switches while introducing a subsequent pulse input to the first switch in each successive cycle. This systolic manner of applying each pulse input of the set of pulse inputs to a respective switch of the array of switches gates the current output from a respective current generation unit of the array of current generation units to a respective integrator circuit of the array of integrator circuits 408. The complete propagation of all pulse inputs of the set of pulse inputs through the master modulated current element 302 requires a latency of 7 cycles for a configuration with four bit-spliced portions, continuing the systolic propagation pattern through remaining cycles of the successive cycles until all pulse inputs of the set of pulse inputs are applied to all switches of the array of switches. During cycles 1 through 3, the bit-spliced portions progressively fill the array positions. During cycle 4, all four bit-spliced portions are aligned across the four positions, generating partial products for all four weight-input combinations simultaneously. During cycles 5 through 7, the bit-spliced portions progressively exit the array. In some non-limiting examples, when the first digital operand and the second digital operand are each 8-bit operands split into four 2-bit portions with a clock frequency of 100 MHz, the complete systolic propagation requires 70 nanoseconds (7 cycles ×10 nanoseconds per cycle). In other non-limiting examples, the signal generation unit 106 is configured to interleave bit-spliced portions from successive instances of the second digital operand such that, during the successive cycles, bit-spliced portions of a current instance of the second digital operand and bit-spliced portions of a previous instance of the second digital operand propagate through the array of switches concurrently, while each current generation unit of the array of current generation units maintains, across the successive cycles, the current output for the respective bit-spliced portion of the first digital operand. In yet other non-limiting examples, the systolic data flow operation may be configured to process operands with different bit widths by adjusting the number of bit-spliced portions and the corresponding number of cycles for complete propagation, where each bit-spliced portion of the first set of bit-spliced portions and each bit-spliced portion of the second set of bit-spliced portions is a p-bit portion, where p is less than N.

FIG. 5 is a block diagram 500 that illustrates a pipelined implementation of the master modulated current element 302 for processing multiple instances of digital operands, in accordance with an embodiment of the disclosure. FIG. 5 is explained in conjunction with elements from FIG. 1, FIG. 2, FIG. 3, and FIG. 4. With reference to FIG. 5, there is shown the block diagram 500. The block diagram 500 depicts how bit-spliced portions propagate through the system in a systolic manner across multiple cycles while enabling interleaved processing of successive operand instances. In the pipelined implementation, the signal generation unit 106 is configured to interleave bit-spliced portions from successive instances of the second digital operand such that, during the successive cycles, bit-spliced portions of a current instance of the second digital operand and bit-spliced portions of a previous instance of the second digital operand propagate through the array of switches concurrently. This configuration enables continuous processing of sequential input samples with high throughput after an initial pipeline fill delay.

As shown in FIG. 5, the master modulated current element 302 receives a first set of bit-spliced portions 502 comprising weight values w₃, w₂, w₁, and w₀ at internal switch input terminals 504. The first set of bit-spliced portions 502 represents bit-spliced portions of a first digital operand stored within the master modulated current element 302. Each current generation unit of the array of current generation units maintains, across the successive cycles, the current output for the respective bit-spliced portion of the first digital operand. The master modulated current element 302 also receives input signals at switch array input terminals 506, which correspond to bit-spliced portions of the second digital operand that propagate through the system across successive cycles. In the pipelined implementation, the weight values stored at the internal switch input terminals 504 remain static while input splices flow through the master modulated current element 302, enabling efficient processing of multiple input instances against a fixed set of weight values. In some non-limiting examples, the first digital operand represents a weight value of a neural network that remains constant during inference operations while successive input values for the neural network are processed through the pipelined architecture.

With continued reference to FIG. 5, the block diagram 500 includes an array of integrator circuits 508 coupled to the master modulated current element 302. The array of integrator circuits 508 comprises four integrator circuits respectively coupled to the array of switches within the master modulated current element 302. Each integrator circuit of the array of integrator circuits 508 receives a current output from a respective current generation unit of the array of current generation units, where the current outputs are designated as I₃ⱼ, I₂ⱼ, I₁ⱼ, and I₀ⱼ, and j represents the cycle index. Each integrator circuit integrates the received current to produce voltage outputs. The array of integrator circuits 508 is reset between successive cycles such that the array of integrator circuits 508 produces, after each cycle of the successive cycles, a subset of voltage outputs of a set of voltage outputs 512. The set of voltage outputs 512 comprises V₃ⱼ, V₂ⱼ, V₁ⱼ, and V₀ⱼ that are produced by the array of integrator circuits 508 during operation.

A voltage output matrix 510 illustrates the organization of voltage outputs across multiple cycles and bit-spliced portion indices. The voltage output matrix 510 is organized with rows corresponding to cycle indices j ranging from 1 to 7 and columns corresponding to bit-spliced portion indices i ranging from 0 to 3. The entries in the voltage output matrix 510 represent individual voltage outputs Vᵢⱼ produced during each cycle for each bit-spliced portion position. The set of voltage outputs corresponds to all pairwise partial products of the first set of bit-spliced portions and the second set of bit-spliced portions. The voltage output matrix 510 demonstrates how the pipelined implementation generates partial products for multiple operand instances concurrently through the interleaving of bit-spliced portions from successive instances.

As further shown in FIG. 5, the block diagram 500 shows previous instance voltage outputs 514 corresponding to voltage outputs generated from bit-spliced portions of a previous instance of the second digital operand. The previous instance voltage outputs 514 are indicated by diagonal shading in the voltage output matrix 510 for entries such as V₃₁, V₃₂, V₂₂, V₃₃, V₂₃, V₁₃, and V₃₄, V₂₄, V₁₄, V₀₄. These voltage outputs correspond to partial products generated when bit-spliced portions x₋₂, x₋₁, and x₋₀ from the previous instance propagate through the array of switches within the master modulated current element 302. The block diagram 500 further shows next instance voltage outputs 516 corresponding to voltage outputs generated from bit-spliced portions of next instance of the second digital operand. The next instance voltage outputs 516 are indicated by diagonal shading for entries such as V₀₅, V₁₆, V₀₆, V₂₇, V₁₇, and V₀₇. These voltage outputs correspond to partial products generated when bit-spliced portions x₃₊, x₂₊, and x₁₊ from the next instance propagate through the array of switches within the master modulated current element 302.

The systolic propagation pattern is illustrated at the bottom of the block diagram 500, showing how input values x₋₂, x₋₁, x₋₀, x₃, x₂, x₁, x₀, x₃₊, x₂₊, and x₁₊ flow through the system across cycles 1 through 7. The notation x₋₂, x₋₁, and x₋₀ represents bit-spliced portions from a previous instance of the second digital operand, while x₃₊, x₂₊, and x₁₊represents bit-spliced portions from a next instance of the second digital operand. In a first cycle of the successive cycles, x₋₂ enters the first position while x₃ enters the fourth position. In subsequent cycles, the bit-spliced portions shift through the positions in accordance with the systolic propagation pattern, with cycle 4 showing x₃, x₂, x₁, and x₀ aligned across all four positions corresponding to the current instance of the second digital operand. The systolic propagation pattern comprises shifting each pulse input to a next switch of the array of switches while introducing a subsequent pulse input to the first switch in each successive cycle. This interleaving of bit-spliced portions from successive instances enables continuous processing with reduced conversion rate while maintaining the specified latency of the pipelined architecture.

The interleaving of bit-spliced portions from successive instances reduces the overall rate of conversion compared to processing each instance independently with idle cycles between instances. Instead of requiring seven cycles with zeros filling positions before and after the active input values as depicted in the block diagram 400 of FIG. 4, the pipelined implementation fills the zero positions with bit-spliced portions from previous and next instances. The previous instance bit-spliced portions x₋₂, x₋₁, and x₋₀ occupy positions that would otherwise contain zeros during the initial fill phase (as shown in FIG. 4), while the next instance bit-spliced portions x₃₊, x₂₊, and x₁₊ occupy positions that would otherwise contain zeros during the drain phase. This interleaving enables the pipelined implementation to achieve higher throughput by processing multiple operand instances concurrently. The ADC array 112a is configured to digitize the set of voltage outputs 512 into a set of digitized partial products and the digital reconstruction unit 112 is configured to combine the set of digitized partial products based on binary shift and add operations to reconstruct a full-precision multiplication result of the first digital operand and the second digital operand. In some non-limiting examples, when processing a continuous stream of N-bit input operands split into N/p p-bit portions against a fixed set of weight values, the pipelined implementation may produce one complete full-precision multiplication result every four cycles after an initial latency of three cycles, compared to seven cycles per result for non-interleaved operation described in FIG. 4. In other non-limiting examples, the pipelined implementation may be configured to process operands with different bit widths by adjusting the number of bit-spliced portions and the corresponding interleaving pattern, where the first digital operand and the second digital operand are each N-bit operands, and each bit-spliced portion of the first set of bit-spliced portions 502 and each bit-spliced portion of the second set of bit-spliced portions is a p-bit portion, where p is less than N.

FIG. 6 is a block diagram 600 that illustrates the master modulated current element 302 configured for broadcast mode operation, in accordance with an embodiment of the disclosure. FIG. 6 is explained in conjunction with elements from FIG. 1, FIG. 2, FIG. 3, FIG. 4, and FIG. 5. With reference to FIG. 6, there is shown the block diagram 600. The block diagram 600 depicts a configuration where the multiplier circuit is configured to operate in a broadcast mode in which a same pulse input of the set of pulse inputs is applied simultaneously to all switches of the array of switches during a single cycle of the successive cycles. In the broadcast mode, the signal generation unit 106 applies each bit-spliced portion of the second set of bit-spliced portions to all current generation units of the array of current generation units concurrently within each cycle, rather than applying each pulse input of the set of pulse inputs to a respective switch of the array of switches in a systolic manner as described with reference to FIG. 4 and FIG. 5.

As shown in FIG. 6, the master modulated current element 302 receives a first set of bit-spliced portions 602 comprising weight values W₃, W₂, W₁, and W₀ arranged horizontally across the top of the master modulated current element 302. The first set of bit-spliced portions 602 represents bit-spliced portions of a first digital operand stored within the master modulated current element 302. The master modulated current element 302 includes internal switch input terminals 604 that receive control signals from the first set of bit-spliced portions 602. The internal switch input terminals 604 are coupled to the set of internal switches within each modulated current element of the master modulated current element 302, enabling the weight values W₃, W₂, W₁, and W₀ to control the set of binary-weighted current sources within each respective modulated current element. In some non-limiting examples, the current DAC of each current generation unit of the array of current generation units comprises memory cells configured to store the bits of the respective bit-spliced portion of the first digital operand, allowing the weight values to remain static across multiple cycles of broadcast mode operation.

With continued reference to FIG. 6, the master modulated current element 302 includes switch array input terminals 606 that receive the set of pulse inputs from the signal generation unit. In the broadcast mode configuration, the switch array input terminals 606 receive a same pulse input that is applied simultaneously to all switches of the array of switches within the master modulated current element 302 during each cycle. The block diagram 600 includes an array of integrator circuits 608 positioned to the left of the master modulated current element 302. The array of integrator circuits 608 comprises four integrator circuits, each represented by an integration symbol, that are respectively coupled to the array of switches and receive current outputs I₃ⱼ, I₂ⱼ, I₁ⱼ, and I₀ⱼ from the master modulated current element 302, where j represents the cycle index. Applying each pulse input of the set of pulse inputs to a respective switch of the array of switches gates the current output from a respective current generation unit of the array of current generation units to a respective integrator circuit of the array of integrator circuits 608. The array of integrator circuits 608 is reset between successive cycles such that the array of integrator circuits 608 produces, after each cycle of the successive cycles, a subset of voltage outputs of a set of voltage outputs 610.

The block diagram 600 further illustrates the set of voltage outputs 610 organized as a table showing the relationship between bit-spliced portion indices and cycle indices. The set of voltage outputs 610 corresponds to all pairwise partial products of the first set of bit-spliced portions 602 and the second set of bit-spliced portions. The set of voltage outputs 610 displays voltage values Vᵢⱼ where i represents the bit-spliced portion index ranging from 0 to 3 and j represents the cycle index ranging from 1 to 4. The table structure shows that for each cycle j, voltage outputs V₃ⱼ, V₂ⱼ, V₁ⱼ, and V₀ⱼ are produced corresponding to the four bit-spliced portions. In the broadcast mode, each cycle generates four partial products simultaneously because the same pulse input is applied to all four switches of the array of switches concurrently. For cycle j equals 1, the voltage outputs V₃₁, V₂₁, V₁₁, and V₀₁ are produced, corresponding to the partial products W₃×x₃, W₂×x₃, W₁×x₃, and W₀×x₃ respectively. For cycle j equals 2, the voltage outputs V₃₂, V₂₂, V₁₂, and V₀₂ are produced, corresponding to the partial products W₃×x₂, W₂×x₂, W₁×x₂, and W₀×x₂ respectively. For cycle j equals 3, the voltage outputs V₃₃, V₂₃, V₁₃, and V₀₃ are produced, corresponding to the partial products W₃×x₁, W₂×x₁, W₁×x₁, and W₀×x₁ respectively. For cycle j equals 4, the voltage outputs V₃₄, V₂₄, V₁₄, and V₀₄ are produced, corresponding to the partial products W₃×x₀, W₂×x₀, W₁×x₀, and W₀×x₀ respectively.

Below the master modulated current element 302, the block diagram 600 shows the broadcast data flow pattern across four cycles. In Cycle 1, input x₃ is applied to all four positions simultaneously, generating partial products for all four weight values W₃, W₂, W₁, and W₀ multiplied by x₃. In Cycle 2, input x₂ is applied to all four positions simultaneously, generating partial products for all four weight values multiplied by x₂. In Cycle 3, input x₁ is applied to all four positions simultaneously, generating partial products for all four weight values multiplied by x₁. In Cycle 4, input x₀ is applied to all four positions simultaneously, generating partial products for all four weight values multiplied by x₀. This broadcast mode operation generates all sixteen pairwise partial products of the first set of bit-spliced portions 602 and the second set of bit-spliced portions in four cycles, with four partial products generated per cycle.

The broadcast mode configuration depicted in the block diagram 600 differs from the systolic mode configuration depicted in the block diagram 400 of FIG. 4 in several aspects. In the systolic mode, applying each pulse input of the set of pulse inputs to a respective switch of the array of switches in a systolic manner comprises, in a first cycle of the successive cycles, applying a first pulse input of the set of pulse inputs to a first switch of the array of switches, and in a second cycle of the successive cycles, applying the first pulse input to a second switch of the array of switches and applying a second pulse input of the set of pulse inputs to the first switch. The systolic propagation pattern comprises shifting each pulse input to a next switch of the array of switches while introducing a subsequent pulse input to the first switch in each successive cycle. The systolic mode requires seven cycles to generate all sixteen partial products for a configuration with four bit-spliced portions, with a diagonal pattern of non-zero voltage outputs across the voltage output matrix. In contrast, the broadcast mode applies the same pulse input to all switches simultaneously during each cycle, generating four partial products per cycle and completing all sixteen partial products in four cycles. The broadcast mode may be suitable when both operands are changing between multiplication operations, as the broadcast mode does not rely on maintaining static weight values across multiple cycles of systolic propagation. The broadcast mode takes 4 cycles for 4 splices, compared to 7 cycles for the systolic mode with 4 splices. In some non-limiting examples, when the first digital operand and the second digital operand are each N-bit operands split into four p-bit portions with a clock frequency of 100 MHz, the broadcast mode may complete a full multiplication operation in 40 nanoseconds (4 cycles ×10 nanoseconds per cycle), compared to 70 nanoseconds for the systolic mode of FIG. 4. The ADC array 112 a is configured to digitize the set of voltage outputs 610 into a set of digitized partial products and the digital reconstruction unit 112 is configured to combine the set of digitized partial products based on binary shift and add operations to reconstruct a full-precision multiplication result of the first digital operand and the second digital operand, regardless of whether the broadcast mode or systolic mode is employed.

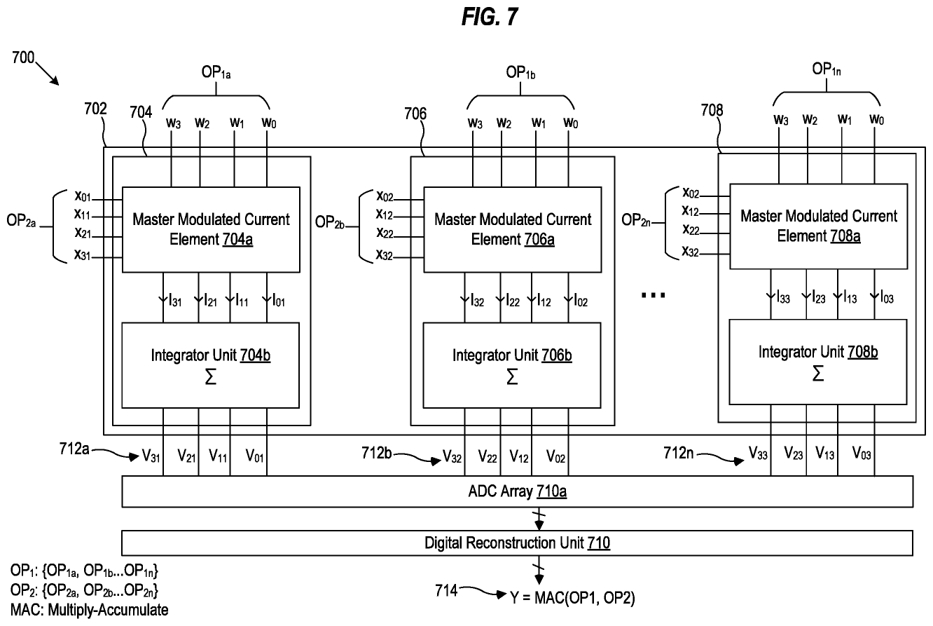

FIG. 7 is a block diagram 700 that illustrates a multiply-accumulate (MAC) circuit 702 comprising a plurality of multiplier circuits, in accordance with an embodiment of the disclosure. FIG. 7 is explained in conjunction with elements from FIG. 1, FIG. 2, FIG. 3, FIG. 4, FIG. 5, and FIG. 6. The MAC circuit 702 is configured to perform multiply-and-accumulate operations using partial precision techniques, where multiple products of digital operand pairs are computed and accumulated to produce a MAC result 714. As described with reference to FIG. 1, each multiplier circuit may be implemented based on an array of modulated current elements (MCEs), where each MCE, as depicted in the diagram 200 of FIG. 2, comprises a set of binary-weighted current sources 204 and a set of internal switches 206 controlled by bits of a bit-spliced portion of a digital operand. Multiple MCEs may be combined to form a master modulated current element (MMCE), as illustrated in the diagram 300 of FIG. 3, where the master modulated current element 302 comprises modulated current elements 304a, 304b, 304c, and 304d arranged in parallel configuration. The multiplier circuit 102 of FIG. 1 illustrates how the array of current generation units 104, each comprising a current DAC implementing an MCE, together with the switching unit 108 and integration unit 110, form the basis for the multiplier circuits within the MAC circuit 702.

The MAC circuit 702 comprises a plurality of multiplier circuits arranged in parallel, including a first multiplier circuit 704, a second multiplier circuit 706, and an n^{th} multiplier circuit 708, indicating that the architecture is scalable to accommodate any number of multiplier circuits. Each multiplier circuit of the plurality of multiplier circuits comprises an array of current generation units, where each current generation unit of the array of current generation units is configured to generate a current output corresponding to a respective bit-spliced portion of a first set of bit-spliced portions of a respective first digital operand. Each multiplier circuit further comprises a signal generation unit configured to generate a set of pulse inputs corresponding to a second set of bit-spliced portions of a respective second digital operand. Each multiplier circuit also comprises a switching unit comprising an array of switches respectively coupled to the array of current generation units. Each multiplier circuit additionally comprises an integration unit comprising an array of integrator circuits respectively coupled to the array of switches. Applying each pulse input of the set of pulse inputs to a respective switch of the array of switches gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions and the second set of bit-spliced portions. In some non-limiting examples, the MAC circuit 702 may comprise two multiplier circuits for computing a dot product of two-element vectors, four multiplier circuits for computing a dot product of four-element vectors, or any number of multiplier circuits for computing dot products in neural network inference operations.

With continued reference to FIG. 7, the first multiplier circuit 704 includes a first master modulated current element 704a and a first integrator unit 704b. The first master modulated current element 704a, similar to the master modulated current element 302 of FIG. 3, comprises an array of current generation units implemented as modulated current elements, where each current generation unit of the array of current generation units is configured to generate a current output corresponding to a respective bit-spliced portion of a first set of bit-spliced portions of a respective first digital operand designated as OP1a. The first master modulated current element 704a receives weight inputs W₃, W₂, W₁, and W₀ representing bit-spliced portions of the first digital operand OP1a. The first multiplier circuit 704 further comprises a signal generation unit configured to generate a set of pulse inputs corresponding to a second set of bit-spliced portions of a respective second digital operand designated as OP2a. The first master modulated current element 704a receives input signals x₀₁, x₁₁, x₂₁, and x₃₁ representing the bit-spliced portions of the second digital operand OP2a. The first master modulated current element 704a generates current outputs I₃₁, I₂₁, I₁₁, and I₀₁ that are directed to the first integrator unit 704b. The first integrator unit 704b comprises an array of integrator circuits respectively coupled to an array of switches within the first master modulated current element 704a. Applying each pulse input of the set of pulse inputs to a respective switch of the array of switches gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs 712a. The first integrator unit 704b produces the set of voltage outputs 712a comprising V₃₁, V₂₁, V₁₁, and V₀₁. The set of voltage outputs 712a corresponds to all pairwise partial products of the first set of bit-spliced portions and the second set of bit-spliced portions for the first multiplier circuit 704.

The second multiplier circuit 706 includes a second master modulated current element 706a and a second integrator unit 706b. The second master modulated current element 706a, configured similarly to the master modulated current element 302 of FIG. 3 with each constituent MCE structured as the modulated current element 202 of FIG. 2, comprises an array of current generation units, wherein each current generation unit of the array of current generation units is configured to generate a current output corresponding to a respective bit-spliced portion of a first set of bit-spliced portions of a respective first digital operand designated as OP1b. The second master modulated current element 706a receives weight inputs W₃, W₂, W₁, and W₀ representing bit-spliced portions of the first digital operand OP1b. The second multiplier circuit 706 further comprises a signal generation unit configured to generate a set of pulse inputs corresponding to a second set of bit-spliced portions of a respective second digital operand designated as OP2b. The second master modulated current element 706a receives input signals x₀₂, x₁₂, x₂₂, and x₃₂ representing the bit-spliced portions of the second digital operand OP2b. The second master modulated current element 706a generates current outputs I₃₂, I₂₂, I₁₂, and I₀₂ that are directed to the second integrator unit 706b. The second integrator unit 706b comprises an array of integrator circuits respectively coupled to an array of switches within the second master modulated current element 706a. Applying each pulse input of the set of pulse inputs to a respective switch of the array of switches gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs 712b. The second integrator unit 706b produces the set of voltage outputs 712b comprising V₃₂, V₂₂, V₁₂, and V₀₂. The set of voltage outputs 712b corresponds to all pairwise partial products of the first set of bit-spliced portions and the second set of bit-spliced portions for the second multiplier circuit 706.

As further shown in FIG. 7, the n^{th} multiplier circuit 708 includes an n^{th} master modulated current element 708a and an n^{th} integrator unit 708b. The n^{th} master modulated current element 708a, which follows the same architectural principles as the master modulated current element 302 of FIG. 3 comprising multiple MCEs as depicted in FIG. 2, comprises an array of current generation units, wherein each current generation unit of the array of current generation units is configured to generate a current output corresponding to a respective bit-spliced portion of a first set of bit-spliced portions of a respective first digital operand designated as OP1n. The n^{th} master modulated current element 708a receives weight inputs W₃, W₂, W₁, and W₀ representing bit-spliced portions of the first digital operand OP1n. The n^{th} multiplier circuit 708 further comprises a signal generation unit configured to generate a set of pulse inputs corresponding to a second set of bit-spliced portions of a respective second digital operand designated as OP2n. The n^{th} master modulated current element 708a receives input signals x₀₂, x₁₂, x₂₂, and x₃₂ representing the bit-spliced portions of the second digital operand OP2n. The n^{th} master modulated current element 708a generates current outputs I₃₃, I₂₃, I₁₃, and I₀₃ that are directed to the n^{th} integrator unit 708b. The n^{th} integrator unit 708b comprises an array of integrator circuits respectively coupled to an array of switches within the n^{th} master modulated current element 708a. Applying each pulse input of the set of pulse inputs to a respective switch of the array of switches gates the current output from a respective current generation unit of the array of current generation units to a respective integrator circuit of the array of integrator circuits. The array of integrator circuits is reset between successive cycles such that the array of integrator circuits produces, after each cycle of the successive cycles, a subset of voltage outputs of a set of voltage outputs 712n. The n^{th} integrator unit 708b produces the set of voltage outputs 712n comprising V₃₃, V₂₃, V₁₃, and V₀₃. The set of voltage outputs 712n corresponds to all pairwise partial products of the first set of bit-spliced portions and the second set of bit-spliced portions for the n^{th} multiplier circuit 708. In some non-limiting examples, the first digital operands OP1a, OP1b through OP1n may represent weight values of a neural network layer, and the second digital operands OP2a, OP2b through OP2n may represent input values for the neural network layer.

With continued reference to FIG. 7, the MAC circuit 702 further includes an ADC array 710a configured to digitize the set of voltage outputs from each multiplier circuit of the plurality of multiplier circuits to obtain a respective set of digitized partial products. The sets of voltage outputs 712a, 712b, and 712n from all multiplier circuits of the plurality of multiplier circuits are provided to the ADC array 710a. The ADC array 710a comprises an array of analog-to-digital converters configured to digitize the sets of voltage outputs 712a, 712b, and 712n into respective sets of digitized partial products. Each analog-to-digital converter of the array of analog-to-digital converters may have a resolution of 2p bits, where p is a bit width of each bit-spliced portion of the first set of bit-spliced portions and the second set of bit-spliced portions. The MAC circuit 702 further includes a digital reconstruction unit 710 configured to combine the respective set of digitized partial products based on shift and add operations to reconstruct, for each multiplier circuit of the plurality of multiplier circuits, a respective full-precision multiplication result of a set of full-precision multiplication results. The shift and add operations comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to reconstruct the full-precision multiplication result. The first shift amount is 2p bits and the second shift amount is p bits, wherein p is a bit width of each bit-spliced portion of the first set of bit-spliced portions and the second set of bit-spliced portions. The digital reconstruction unit 710 is further configured to add the set of full-precision multiplication results from the plurality of multiplier circuits to produce a MAC result 714. The MAC result 714 represents the computation Y=MAC(OP₁, OP₂), where OP₁ comprises the set of first digital operands OP₁ₐ, OP_{1b} through OP₁ₙ, and OP₂ comprises the set of second digital operands OP₂ₐ, OP_{2b} through OP₂ₙ. In some non-limiting examples, the digital reconstruction unit 710 may comprise a combinational logic circuit configured to perform the shift and add operations, followed by an accumulator circuit configured to sum the full-precision multiplication results from all multiplier circuits. In other non-limiting examples, when the MAC circuit 702 comprises four multiplier circuits processing 8-bit operands split into four 2-bit portions, the MAC result 714 represents the sum OP₁ₐ×OP₂ₐ+OP_{1b}×OP_{2b}+OP_{1c}×OP_{2c}+OP_{1d}×OP_{2d}, which corresponds to a dot product of two four-element vectors.

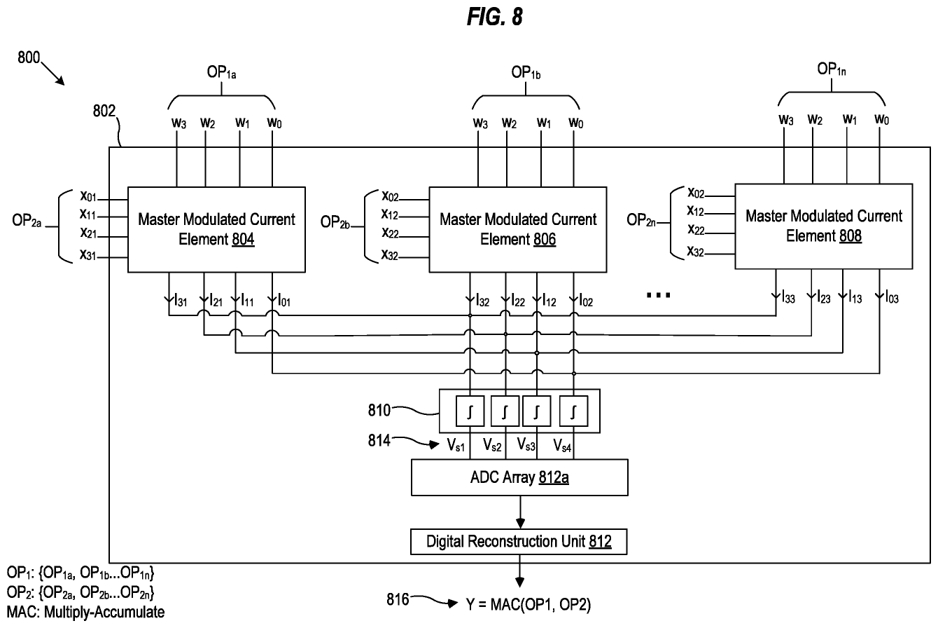

FIG. 8 is a block diagram 800 that illustrates a MAC circuit 802 with shared integrator circuits, in accordance with an embodiment of the disclosure. FIG. 8 is explained in conjunction with elements from FIG. 1, FIG. 2, FIG. 3, FIG. 4, FIG. 5, FIG. 6, and FIG. 7. The MAC circuit 802 is configured to perform multiply-and-accumulate operations using partial precision techniques, where current outputs from corresponding bit positions across a plurality of master modulated current elements are shorted together before integration to enable accumulation of partial products with the same significance level in the analog domain.

The MAC circuit 802 comprises a plurality of master modulated current elements arranged in parallel, including a master modulated current element 804, a master modulated current element 806, and a master modulated current element 808. Each master modulated current element of the plurality of master modulated current elements comprises an array of current generation units, wherein each current generation unit of the array of current generation units is configured to generate a current output corresponding to a respective bit-spliced portion of a first set of bit-spliced portions of a respective first digital operand. The MAC circuit 802 further comprises an array of integrator circuits 810 coupled to the plurality of master modulated current elements, an ADC array 812a coupled to the array of integrator circuits 810, a digital reconstruction unit 812 coupled to the ADC array 812a, and produces a MAC result 816. In some non-limiting examples, the MAC circuit 802 may be implemented within an analog compute-in-memory (ACIM) system for neural network inference, where the first digital operand represents a weight value of a neural network and the second digital operand represents an input value for the neural network.

As shown in FIG. 8, each master modulated current element of the plurality of master modulated current elements receives a respective first digital operand and a respective second digital operand. The master modulated current element 804 receives a first digital operand designated as OP₁ₐ and a second digital operand designated as OP₂ₐ. The master modulated current element 806 receives a first digital operand designated as OP_{1b} and a second digital operand designated as OP_{2b}. The master modulated current element 808 receives a first digital operand designated as OP₁ₙ and a second digital operand designated as OP₂ₙ. The first digital operands OP₁ comprise the set OP₁ₐ, OP_{1b} through OP₁ₙ, and the second digital operands OP₂ comprise the set OP₂ₐ, OP_{2b} through OP₂ₙ. Each master modulated current element includes a first set of bit-spliced portions comprising weight values W₃, W₂, W₁, and W₀ representing bit-spliced portions of the respective first digital operand, and receives a second set of bit-spliced portions comprising input values x₀₂, x₁₂, x₂₂, and x₃₂ representing bit-spliced portions of the respective second digital operand. Each master modulated current element further comprises a signal generation unit configured to generate a set of pulse inputs corresponding to the second set of bit-spliced portions of the respective second digital operand, and a switching unit comprising an array of switches respectively coupled to the array of current generation units. Applying each pulse input of the set of pulse inputs to a respective switch of the array of switches gates the current output from a respective current generation unit of the array of current generation units. The master modulated current element 804 generates current outputs I₃₁, I₂₁, I₁₁, and I₀₁. The master modulated current element 806 generates current outputs I₃₂, I₂₂, I₁₂, and I₀₂. The master modulated current element 808 generates current outputs I₃₃, I₂₃, I₁₃, and I₀₃. In some non-limiting examples, the first digital operands OP₁ₐ, OP_{1b} through OP₁ₙ may represent weight values of a neural network layer, and the second digital operands OP₂ₐ, OP_{2b} through OP₂ₙ may represent input activation values for the neural network layer.

With continued reference to FIG. 8, the current outputs from corresponding bit positions across all master modulated current elements 804, 806, and 808 are shorted together before integration. Specifically, the current outputs corresponding to bit-splice index i=3 from all master modulated current elements (I₃₁ from the master modulated current element 804, I₃₂ from the master modulated current element 806, and I₃₃ from the master modulated current element 808) are shorted together at a common node. Similarly, the current outputs corresponding to bit-splice index i=2 (I₂₁, I₂₂, and I₂₃) are shorted together at a second common node, the current outputs corresponding to bit-splice index i=1 (I₁₁, I₁₂, and I₁₃) are shorted together at a third common node, and the current outputs corresponding to bit-splice index i=0 (I₀₁, I₀₂, and I₀₃) are shorted together at a fourth common node. This node shorting configuration enables accumulation of partial products with the same significance level in the analog domain, implementing the vector dot product operation Σxᵢ·wᵢ directly through current summation at each common node. The set of voltage outputs corresponds to all pairwise partial products of the first set of bit-spliced portions and the second set of bit-spliced portions accumulated across the plurality of master modulated current elements. For example, the current at the common node for bit-splice index i=3 represents the sum of all partial products corresponding to the MSB×MSB position across all weight-input pairs processed by the master modulated current elements 804, 806, and 808.

The array of integrator circuits 810 is coupled to the common nodes where the current outputs from corresponding bit positions are connected together. The array of integrator circuits 810 comprises an array of integrator circuits respectively coupled to the array of switches, wherein the array of integrator circuits comprises four integrator circuits that accumulate the summed currents from the master modulated current elements 804, 806, and 808 to produce a set of voltage outputs 814 comprising Vₛ₁, Vₛ₂, Vₛ₃, and Vₛ₄. Each integrator circuit of the array of integrator circuits 810 is one of a capacitor-based circuit or an operational amplifier-based circuit that receives the summed current from a respective common node and integrates the summed current over time to produce a corresponding voltage output. The voltage output Vₛ₁ corresponds to the accumulated partial products from bit-splice index i=3 across all master modulated current elements. The voltage output Vₛ₂ corresponds to the accumulated partial products from bit-splice index i=2 across all master modulated current elements. The voltage output Vₛ₃ corresponds to the accumulated partial products from bit-splice index i=1 across all master modulated current elements. The voltage output Vₛ₄ corresponds to the accumulated partial products from bit-splice index i=0 across all master modulated current elements. The array of integrator circuits 810 is reset between successive cycles such that the array of integrator circuits 810 produces, after each cycle of the successive cycles, a subset of voltage outputs of the set of voltage outputs 814. In some non-limiting examples, each integrator circuit of the array of integrator circuits 810 may be a capacitor-based circuit where the capacitor accumulates charge from the summed current during each cycle and is discharged by a reset signal prior to the next cycle.

As further shown in FIG. 8, the set of voltage outputs 814 is provided to the ADC array 812a. The ADC array 812a is configured to digitize the set of voltage outputs 814 into a set of digitized partial products. The ADC array 812a comprises an array of analog-to-digital converters configured to digitize the set of voltage outputs 814 into the set of digitized partial products. Each analog-to-digital converter of the array of analog-to-digital converters has a resolution of 2p+log₂n bits, wherein p is a bit width of each bit-spliced portion of the first set of bit-spliced portions and the second set of bit-spliced portions, and n is the number of master modulated current elements, to accommodate the accumulated partial products from multiple weight-input pairs. The digital reconstruction unit 812 is configured to combine the set of digitized partial products based on binary shift and add operations to produce the MAC result 816 designated as Y=MAC(OP₁, OP₂). The digital reconstruction unit 812 is further configured to combine the set of digitized partial products based on shift and add operations to reconstruct a full-precision multiplication result for each multiplier circuit and add the set of full-precision multiplication results from the plurality of master modulated current elements to produce the MAC result 816. The shift and add operations comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to produce the MAC result 816. The first shift amount is 2p bits and the second shift amount is p bits, where p is a bit width of each bit-spliced portion of the first set of bit-spliced portions and the second set of bit-spliced portions. The MAC result 816 represents the sum of products of corresponding pairs of first and second digital operands processed through the partial precision bit splicing technique, implementing the computation Y=OP₁ₐ×OP₂ₐ+OP_{1b}×OP_{2b}+ . . .+OP₁ₙ×OP₂ₙ.

The MAC circuit 802 depicted in the block diagram 800 differs from the MAC circuit 702 depicted in the block diagram 700 of FIG. 7 in the configuration of the integration unit. In the MAC circuit 702, each multiplier circuit of the plurality of multiplier circuits comprises an integration unit comprising an array of integrator circuits respectively coupled to the array of switches, and the ADC array 710a digitizes the set of voltage outputs from each multiplier circuit of the plurality of multiplier circuits to obtain a respective set of digitized partial products, and the digital reconstruction unit 710 combines the respective set of digitized partial products based on shift and add operations to reconstruct, for each multiplier circuit of the plurality of multiplier circuits, a respective full-precision multiplication result of a set of full-precision multiplication results, and adds the set of full-precision multiplication results from the plurality of multiplier circuits to produce the MAC result 714. In contrast, in the MAC circuit 802, the current outputs from corresponding bit positions across all master modulated current elements 804, 806, and 808 are shorted together before integration, and the shared array of integrator circuits 810 accumulates the summed currents to produce the set of voltage outputs 814. This node shorting configuration enables the MAC circuit 802 to perform the accumulation operation in the analog domain through current summation, reducing the number of integrator circuits and analog-to-digital converters compared to the MAC circuit 702. For example, when the MAC circuit 802 comprises three master modulated current elements processing N-bit operands split into four p-bit portions, wherein p is less than N, the MAC circuit 802 may use four integrator circuits and four analog-to-digital converters in the shared array of integrator circuits 810, compared to twelve integrator circuits and twelve analog-to-digital converters that would be used in a configuration with separate integration units for each master modulated current element. In some non-limiting examples, the first set of bit-spliced portions comprises N/p bit-spliced portions and the second set of bit-spliced portions comprises N/p bit-spliced portions, and the MAC circuit 802 may be configured to process operands with different bit widths by adjusting the number of bit-spliced portions and the corresponding number of integrator circuits in the array of integrator circuits 810.

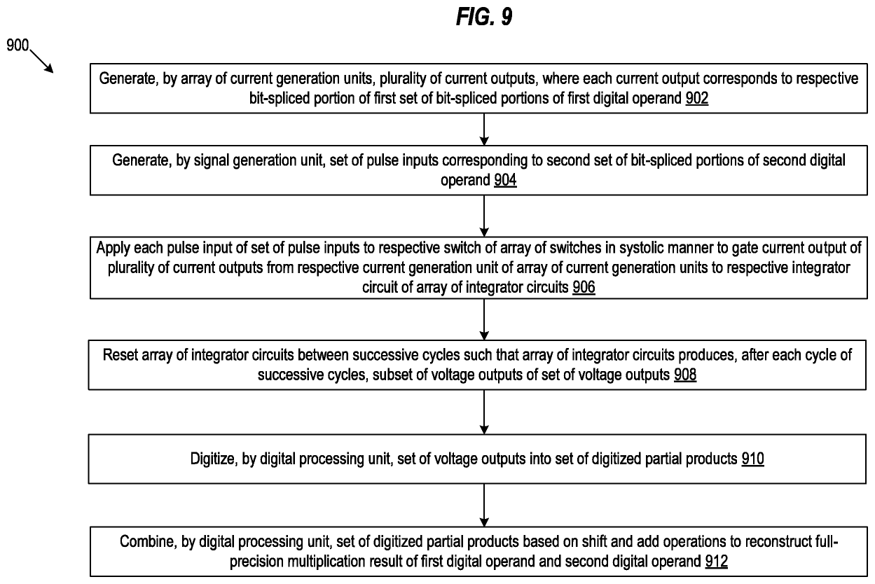

FIG. 9 is a flowchart that illustrates a method for performing hybrid analog-digital multiplication using partial precision and bit splicing techniques, in accordance with an embodiment of the disclosure. FIG. 9 is explained in conjunction with elements from FIG. 1, FIG. 2, FIG. 3, FIG. 4, FIG. 5, FIG. 6, FIG. 7, and FIG. 8. With reference to FIG. 9, there is shown a flowchart 900. The operations of the exemplary method may be executed by the multiplier circuit 102 of FIG. 1, the MAC circuit 702 of FIG. 7, or the MAC circuit 802 of FIG. 8. The flowchart 900 depicts a sequence of operations from 902 to 912 for performing hybrid analog-digital multiplication where analog computation of partial products is combined with digital post-processing to reconstruct a full-precision multiplication result of a first digital operand and a second digital operand.

At 902, the operations include generating, by an array of current generation units, a plurality of current outputs, wherein each current output corresponds to a respective bit-spliced portion of a first set of bit-spliced portions of a first digital operand. In an embodiment of the disclosure, the array of current generation units 104 generates the plurality of current outputs, wherein each current generation unit of the array of current generation units 104 is configured to generate a current output corresponding to a respective bit-spliced portion of the first set of bit-spliced portions 118 of the first digital operand. Each current generation unit of the array of current generation units 104 comprises a current digital-to-analog converter (DAC), and the current DAC includes a set of binary-weighted current sources and a set of internal switches respectively coupled to the set of binary-weighted current sources. The set of internal switches is controlled by bits of the respective bit-spliced portion of the first digital operand. For example, when the first digital operand is an 8-bit value split into four 2-bit portions, the current generation unit 114 a generates a current output corresponding to the bit-spliced portion w₃, the current generation unit 114b generates a current output corresponding to the bit-spliced portion w₂, the current generation unit 114c generates a current output corresponding to the bit-spliced portion w₁, and the current generation unit 114d generates a current output corresponding to the bit-spliced portion w₀. In some non-limiting examples, the current DAC of each current generation unit of the array of current generation units 104 comprises memory cells configured to store the bits of the respective bit-spliced portion of the first digital operand, allowing the weight values to remain static across multiple cycles of operation. In other non-limiting examples, the first digital operand represents a weight value of a neural network, and the second digital operand represents an input value for the neural network. Once the plurality of current outputs is generated by the array of current generation units 104, the method proceeds to generate pulse inputs corresponding to the second digital operand.

At 904, the operations include generating, by a signal generation unit, a set of pulse inputs corresponding to a second set of bit-spliced portions of a second digital operand. In an embodiment of the disclosure, the signal generation unit 106 generates the set of pulse inputs corresponding to the second set of bit-spliced portions 120 of the second digital operand. Each pulse input of the set of pulse inputs has a pulse width corresponding to a value of a respective bit-spliced portion of the second set of bit-spliced portions 120. For example, when the second digital operand is an 8-bit value split into four 2-bit portions, the signal generation unit 106 generates pulse inputs S₃, S₂, S₁, and S₀ corresponding to the bit-spliced portions x₃, x₂, x₁, and x₀ respectively. In some embodiments, the signal generation unit 106 comprises a cascaded array of shift registers and an array of pulse width modulation circuits respectively coupled to the cascaded array of shift registers. The cascaded array of shift registers is configured to sequentially shift each bit-spliced portion of the second set of bit-spliced portions 120 to effectuate the systolic manner. Each pulse width modulation circuit of the array of pulse width modulation circuits is configured to receive a bit-spliced portion of the second set of bit-spliced portions 120 from a respective shift register of the cascaded array of shift registers and generate a respective pulse input of the set of pulse inputs based on the received bit-spliced portion. In some non-limiting examples, when the bit-spliced portion x₃ has a decimal value of 3 and the unit time period Tᵤ=50 nanoseconds, the corresponding pulse input S₃ has a pulse width of 150 nanoseconds (3×50 nanoseconds). With the set of pulse inputs generated, the method proceeds to apply each pulse input to a respective switch of an array of switches to gate the current outputs to the integrator circuits.

At 906, the operations include applying each pulse input of the set of pulse inputs to a respective switch of an array of switches in a systolic manner to gate a current output of the plurality of current outputs from a respective current generation unit of the array of current generation units to a respective integrator circuit of an array of integrator circuits. In an embodiment of the disclosure, the switching unit 108 comprises the array of switches respectively coupled to the array of current generation units 104. Applying each pulse input of the set of pulse inputs to a respective switch of the array of switches in a systolic manner gates the current output from a respective current generation unit of the array of current generation units 104 to a respective integrator circuit of the array of integrator circuits. The applying of each pulse input of the set of pulse inputs to the respective switch of the array of switches in the systolic manner comprises, in a first cycle of the successive cycles, applying a first pulse input of the set of pulse inputs to a first switch of the array of switches. In a second cycle of the successive cycles, the applying comprises applying the first pulse input to a second switch of the array of switches and applying a second pulse input of the set of pulse inputs to the first switch. The systolic propagation pattern comprises shifting each pulse input to a next switch of the array of switches while introducing a subsequent pulse input to the first switch in each successive cycle. The systolic propagation pattern continues through remaining cycles of the successive cycles until all pulse inputs of the set of pulse inputs are applied to all switches of the array of switches. In some embodiments, the multiplier circuit 102 is configured to operate in a broadcast mode in which a same pulse input of the set of pulse inputs is applied simultaneously to all switches of the array of switches during a single cycle of the successive cycles, as depicted in the block diagram 600 of FIG. 6. In some non-limiting examples, when the pulse input S₃ is applied to a switch of the switching unit 108, the switch closes for a duration corresponding to the value of x₃, allowing the current from the corresponding current generation unit to flow to the respective integrator circuit. Following the gating of current outputs to the integrator circuits, the method proceeds to reset the array of integrator circuits between successive cycles to produce voltage outputs corresponding to partial products.

At 908, the operations include resetting the array of integrator circuits between successive cycles such that the array of integrator circuits produces, after each cycle of the successive cycles, a subset of voltage outputs of a set of voltage outputs, wherein the set of voltage outputs corresponds to all pairwise partial products of the first set of bit-spliced portions and the second set of bit-spliced portions. In an embodiment of the disclosure, the integration unit 110 comprises the array of integrator circuits respectively coupled to the array of switches. The array of integrator circuits is reset between successive cycles such that the array of integrator circuits produces, after each cycle of the successive cycles, a subset of voltage outputs of a set of voltage outputs. The set of voltage outputs corresponds to all pairwise partial products of the first set of bit-spliced portions 118 and the second set of bit-spliced portions 120. The reset signal 124 resets the array of integrator circuits between successive cycles by discharging any accumulated charge on the integrator circuits to establish a known initial state prior to each cycle of operation. Each integrator circuit of the array of integrator circuits is one of a capacitor-based circuit or an operational amplifier-based circuit configured to accumulate charge from the gated current output over the duration of the corresponding pulse input. For example, when the first set of bit-spliced portions 118 comprises four 2-bit portions and the second set of bit-spliced portions 120 comprises four 2-bit portions, the set of voltage outputs comprises sixteen partial products corresponding to all pairwise combinations of the bit-spliced portions. In some non-limiting examples, the signal generation unit 106 is configured to interleave bit-spliced portions from successive instances of the second digital operand such that, during the successive cycles, bit-spliced portions of a current instance of the second digital operand and bit-spliced portions of a previous instance of the second digital operand propagate through the array of switches concurrently, as depicted in the block diagram 500 of FIG. 5. After the set of voltage outputs is produced by the array of integrator circuits, the method proceeds to digitize the set of voltage outputs into a set of digitized partial products.

At 910, the operations include digitizing, by an ADC array, the set of voltage outputs into a set of digitized partial products. In an embodiment of the disclosure, the ADC array 112a digitizes the set of voltage outputs into the set of digitized partial products. The ADC array 112a comprises an array of analog-to-digital converters configured to digitize the set of voltage outputs into the set of digitized partial products. Each analog-to-digital converter of the array of analog-to-digital converters has a resolution of 2p bits, wherein p is a bit width of each bit-spliced portion of the first set of bit-spliced portions 118 and the second set of bit-spliced portions 120. For example, when each bit-spliced portion is 2 bits wide (p=2), each analog-to-digital converter has a resolution of 4 bits (2×2=4 bits), which is sufficient to represent the maximum partial product value of 3×3=9. In contrast, a conventional implementation processing full 8-bit operands would require an analog-to-digital converter with 18-bit resolution (8+8+log₂(4)=18 bits for 4 accumulations), demonstrating a reduction in analog-to-digital converter complexity through the bit splicing technique. In some non-limiting examples, the array of analog-to-digital converters may comprise successive approximation register (SAR) analog-to-digital converters, flash analog-to-digital converters, or sigma-delta analog-to-digital converters depending on the speed and resolution requirements of the multiplier circuit 102. Once the set of voltage outputs is digitized into the set of digitized partial products, the method proceeds to combine the set of digitized partial products to reconstruct the full-precision multiplication result.

At 912, the operations include combining, by a digital reconstruction unit, the set of digitized partial products based on shift and add operations to reconstruct a full-precision multiplication result of the first digital operand and the second digital operand. In an embodiment of the disclosure, the digital reconstruction unit 112 combines the set of digitized partial products based on binary shift and add operations to reconstruct the full-precision multiplication result 122 of the first digital operand and the second digital operand. The shift and add operations comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to reconstruct the full-precision multiplication result 122. The first shift amount is 2p bits and the second shift amount is p bits, wherein p is a bit width of each bit-spliced portion of the first set of bit-spliced portions 118 and the second set of bit-spliced portions 120. For example, when p=2 bits, the partial product corresponding to the MSB×MSB position is left-shifted by 4 bits (2p=4), the partial products corresponding to the MSB×LSB and LSB×MSB positions are left-shifted by 2 bits (p=2), and the partial product corresponding to the LSB×LSB position is not shifted. The digital reconstruction unit 112 comprises a combinational logic circuit configured to perform the shift and add operations. In some non-limiting examples, when multiplying X=11 (binary 1011) by Y=13 (binary 1101) using 2-bit splices, the partial products BD=3, AD=2, BC=9, and AC=6 are combined as 3+(2 +9)<<2+6<<4=3+44+96=143, which equals 11×13. Upon completion of the shift and add operations, the full-precision multiplication result 122 of the first digital operand and the second digital operand is reconstructed, thereby completing the method for performing hybrid analog-digital multiplication.

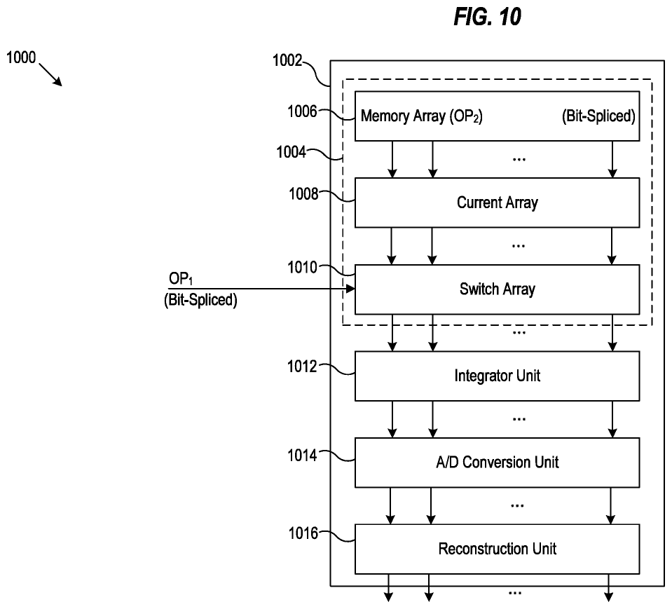

FIG. 10 is a block diagram that illustrates a multiplier circuit comprising a memory array, a current array, a switch array, an integrator unit, an A/D conversion unit, and a reconstruction unit for partial precision analog computing with bit splicing. FIG. 10 is explained in conjunction with elements from FIG. 1, FIG. 2, FIG. 3, FIG. 4, FIG. 5, FIG. 6, FIG. 7, FIG. 8, and FIG. 9. With reference to FIG. 10, there is shown a block diagram 1000 of a multiplier circuit 1002. The multiplier circuit 1002 is configured to perform multiplication operations on digital operands by splitting the digital operands into bit-spliced portions and processing the bit-spliced portions across multiple cycles to generate partial products that are subsequently combined to reconstruct a full-precision multiplication result of a first digital operand and a second digital operand. The multiplier circuit 1002 comprises a memory array 1006, a current array 1008, a switch array 1010, an integrator unit 1012, an A/D conversion unit 1014, and a reconstruction unit 1016.

As shown in FIG. 10, the multiplier circuit 1002 receives a first digital operand 1004 designated as OP1 in bit-spliced form. The first digital operand 1004 comprises a first set of bit-spliced portions that are provided to the switch array 1010 for gating current outputs from the current array 1008. The memory array 1006 is configured to store a second operand designated as OP2 in bit-spliced format. The memory array 1006 stores a second set of bit-spliced portions of the second operand OP2, where each bit-spliced portion of the second set of bit-spliced portions is stored within the memory array 1006 for subsequent processing. In some non-limiting examples, the memory array 1006 may be implemented using static random-access memory (SRAM) cells, dynamic random-access memory (DRAM) cells, or non-volatile memory cells such as flash memory or resistive random-access memory (ReRAM) cells. In other non-limiting examples, when the second operand OP2 is an 8-bit value split into four 2-bit portions, the memory array 1006 stores the four 2-bit portions in respective memory locations for controlling the current array 1008.

With continued reference to FIG. 10, the memory array 1006 is coupled to the current array 1008 and provides control signals to the current array 1008 based on the stored bit-spliced portions of the second operand OP2. The current array 1008 is configured to generate current outputs corresponding to the bit-spliced portions stored in the memory array 1006. The current array 1008 receives control signals from the memory array 1006 to produce binary-weighted currents based on the stored bit values. Each current generation unit within the current array 1008 comprises a current digital-to-analog converter (DAC) that includes a set of binary-weighted current sources and a set of internal switches respectively coupled to the set of binary-weighted current sources, as described with reference to the modulated current element 202 of FIG. 2. The set of internal switches within each current generation unit is controlled by bits of the respective bit-spliced portion of the second operand OP2 stored in the memory array 1006. In some non-limiting examples, the current array 1008 may comprise four current generation units when processing 8-bit operands split into four 2-bit portions, where each current generation unit generates a current output proportional to the value of the respective bit-spliced portion stored in the memory array 1006.

The switch array 1010 is coupled to the current array 1008 and receives the first digital operand 1004 designated as OP1 in bit-spliced form. The switch array 1010 comprises an array of switches that gate the current outputs from the current array 1008 based on pulse inputs corresponding to the bit-spliced portions of the first operand OP1. The switch array 1010 controls the flow of current to the integrator unit 1012 based on the timing and duration of the pulse inputs derived from the first digital operand 1004. Applying each pulse input corresponding to a bit-spliced portion of the first operand OP1 to a respective switch of the switch array 1010 gates a current output from a respective current generation unit of the current array 1008 to the integrator unit 1012. In some non-limiting examples, the switch array 1010 may be implemented using NMOS transistors, PMOS transistors, or transmission gates, where each switch is controlled by a respective pulse input signal derived from the bit-spliced portions of the first operand OP1. In other non-limiting examples, when the first operand OP1 is an 8-bit value split into four 2-bit portions, the switch array 1010 receives pulse inputs with pulse widths corresponding to the values of the four 2-bit portions and gates the current outputs from the current array 1008 accordingly.

As further shown in FIG. 10, the integrator unit 1012 is coupled to the switch array 1010 and comprises an array of integrator circuits that accumulate the gated current outputs over time to produce analog voltage outputs. The integrator unit 1012 integrates the current signals from the switch array 1010 to generate analog voltage values representing partial products of the bit-spliced portions. Each integrator circuit of the integrator unit 1012 is one of a capacitor-based circuit or an operational amplifier-based circuit configured to accumulate charge from the gated current output over the duration of the corresponding pulse input. The integrator unit 1012 is reset between successive cycles such that the integrator unit 1012 produces, after each cycle of the successive cycles, a subset of voltage outputs of a set of voltage outputs. The set of voltage outputs corresponds to all pairwise partial products of the first set of bit-spliced portions of the first operand OP1 and the second set of bit-spliced portions of the second operand OP2 stored in the memory array 1006. In some non-limiting examples, when processing 8-bit operands split into four 2-bit portions, the integrator unit 1012 may comprise four integrator circuits that produce four voltage outputs per cycle, with the complete set of sixteen partial products generated across multiple cycles of operation.

The A/D conversion unit 1014 is coupled to the integrator unit 1012 and is configured to digitize the analog voltage outputs from the integrator unit 1012 into digitized partial products. The A/D conversion unit 1014 converts the analog voltage values into digital representations for subsequent processing by the reconstruction unit 1016. The A/D conversion unit 1014 comprises an array of analog-to-digital converters configured to digitize the set of voltage outputs into the set of digitized partial products. Each analog-to-digital converter of the A/D conversion unit 1014 has a resolution of 2p bits, where p is a bit width of each bit-spliced portion of the first set of bit-spliced portions and the second set of bit-spliced portions. In some non-limiting examples, when each bit-spliced portion is 2 bits wide (p=2), each analog-to-digital converter of the A/D conversion unit 1014 has a resolution of 4 bits (2×2=4 bits), which is sufficient to represent the maximum partial product value of 3×3=9.

The reconstruction unit 1016 is coupled to the A/D conversion unit 1014 and is configured to combine the digitized partial products based on binary shift and add operations to reconstruct a full-precision multiplication result of the first digital operand 1004 and the second operand OP2 stored in the memory array 1006. The reconstruction unit 1016 performs digital post-processing to align and sum the partial products according to their significance levels. The shift and add operations performed by the reconstruction unit 1016 comprise a left shifting of a first subset of the set of digitized partial products by a first shift amount corresponding to a first significance level, a left shifting of a second subset of the set of digitized partial products by a second shift amount corresponding to a second significance level different from the first significance level, and an addition of the left-shifted first subset, the left-shifted second subset, and a third subset of the set of digitized partial products to reconstruct the full-precision multiplication result. The first shift amount is 2p bits and the second shift amount is p bits, where p is a bit width of each bit-spliced portion. In some non-limiting examples, the reconstruction unit 1016 may comprise a combinational logic circuit configured to perform the shift and add operations. In other non-limiting examples, the shift operations may be implemented using hardwired connections that route the digitized partial product bits to appropriate bit positions in an accumulator register within the reconstruction unit 1016.

The block diagram 1000 shows the data flow through the multiplier circuit 1002, with ellipses indicating that additional parallel processing paths may be present for handling multiple bit-spliced portions simultaneously. The dashed lines within the block diagram 1000 indicate the boundaries between the analog processing stages comprising the memory array 1006, the current array 1008, the switch array 1010, and the integrator unit 1012, and the digital reconstruction stage comprising the A/D conversion unit 1014 and the reconstruction unit 1016. The multiplier circuit 1002 depicted in the block diagram 1000 provides an alternative configuration to the multiplier circuit 102 depicted in the diagram 100 of FIG. 1, where the memory array 1006 stores the second operand OP2 and provides control signals to the current array 1008, while the first digital operand 1004 is provided to the switch array 1010 in bit-spliced form. In some non-limiting examples, the multiplier circuit 1002 may be implemented as part of an analog compute-in-memory (ACIM) system for neural network inference, where the second operand OP2 stored in the memory array 1006 represents a weight value of a neural network and the first digital operand 1004 represents an input activation value for the neural network.

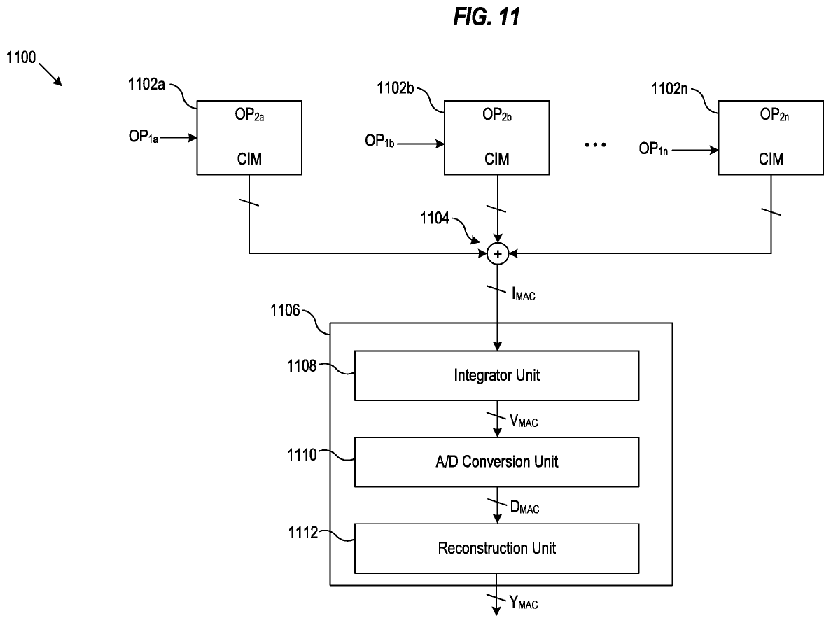

FIG. 11 is a block diagram that illustrates a MAC circuit 1100 comprising a plurality of CIM blocks with a shared summation node 1104, an integrator unit 1108, an A/D conversion unit 1110, and a reconstruction unit 1112 for partial precision analog computing. FIG. 11 is explained in conjunction with elements from FIG. 1, FIG. 2, FIG. 3, FIG. 4, FIG. 5, FIG. 6, FIG. 7, FIG. 8, FIG. 9, and FIG. 10. With reference to FIG. 11, there is shown the MAC circuit 1100. The MAC circuit 1100 is configured to perform multiply-and-accumulate operations using partial precision techniques, where current outputs from corresponding bit positions across a plurality of compute-in-memory (CIM) blocks are shorted together at the summation node 1104 before integration to enable accumulation of partial products with the same significance level in the analog domain.

The MAC circuit 1100 comprises a plurality of CIM blocks arranged in parallel, including a first CIM block 1102a, a second CIM block 1102b, and an n^{th} CIM block 1102n, indicating that the architecture is scalable to accommodate any number of CIM blocks. Each CIM block of the plurality of CIM blocks is configured to generate current outputs corresponding to partial products of respective digital operands. The first CIM block 1102a receives a first digital operand designated as OP1a and a second digital operand designated as OP2a. The second CIM block 1102b receives a first digital operand designated as OP1b and a second digital operand designated as OP2b. The n^{th} CIM block 1102n receives a first digital operand designated as OP1n and a second digital operand designated as OP2n. Each CIM block performs multiplication between its respective operand pairs using the partial precision bit splicing technique, where each operand is split into bit-spliced portions and processed to generate current outputs representing partial products. In some non-limiting examples, each CIM block may be implemented using a master modulated current element comprising an array of current generation units, where each current generation unit of the array of current generation units is configured to generate a current output corresponding to a respective bit-spliced portion of a first set of bit-spliced portions of the respective first digital operand, as described with reference to the master modulated current element 302 of FIG. 3. In other non-limiting examples, the first digital operands OP1a, OP1b through OP1n may represent weight values of a neural network layer, and the second digital operands OP2a, OP2b through OP2n may represent input activation values for the neural network layer.

As further shown in FIG. 11, the current outputs from corresponding bit positions across the first CIM block 1102a, the second CIM block 1102b, and the n^{th} CIM block 1102n are connected to the summation node 1104. The summation node 1104 combines current outputs from corresponding bit positions across all CIM blocks of the plurality of CIM blocks to produce summed currents I_{MAC}, where the slash mark on the arrow in FIG. 11 indicates multiple parallel current paths corresponding to each bit-splice position. The summation node 1104 enables accumulation of partial products with the same significance level in the analog domain through current summation, where the currents from corresponding bit positions across all CIM blocks are shorted together at respective common nodes before integration. The summed currents I_{MAC} represent the aggregate of partial products from corresponding bit-splice positions generated by the plurality of CIM blocks during each cycle of operation. In some non-limiting examples, the summation node 1104 may be implemented as wire connections that short together the current output terminals from corresponding bit positions of all CIM blocks, allowing the currents to sum according to Kirchhoff's current law. In other non-limiting examples, when the MAC circuit 1100 comprises three CIM blocks processing 8-bit operands split into four 2-bit portions, the summation node 1104 comprises four common nodes (one for each bit-splice index), and the summed currents I_{MAC} at each common node represent the sum of partial products from all three weight-input pairs for the respective bit-splice position during each cycle.

With continued reference to FIG. 11, the summed currents I_{MAC} from the summation node 1104 are provided to an external processing unit 1106. The external processing unit 1106 comprises the integrator unit 1108, the A/D conversion unit 1110, and the reconstruction unit 1112 arranged in a sequential processing pipeline. The external processing unit 1106 is configured to receive the summed currents I_{MAC} from the summation node 1104 and process the summed currents to produce a final MAC result Y_{MAC}.

The integrator unit 1108 receives the summed currents I_{MAC} from the summation node 1104 and comprises an array of integrator circuits that integrate the summed currents over time to produce analog voltage outputs V_{MAC}. Each integrator circuit of the array of integrator circuits accumulates charge from a respective summed current corresponding to a respective bit-splice position during each cycle of operation. Each integrator circuit of the integrator unit 1108 may be one of a capacitor-based circuit or an operational amplifier-based circuit configured to accumulate charge from the respective summed current over the duration of the corresponding pulse inputs applied to the CIM blocks. The integrator unit 1108 is reset between successive cycles such that the integrator unit 1108 produces, after each cycle of the successive cycles, voltage outputs V_{MAC} corresponding to the accumulated partial products for that cycle. In some non-limiting examples, each integrator circuit of the integrator unit 1108 may be implemented as a capacitor with capacitance C connected between a respective common node of the summation node 1104 and ground, where the voltage across the capacitor equals (1/C)∫I_{MAC}dt. In other non-limiting examples, each integrator circuit of the integrator unit 1108 may be implemented as an operational amplifier-based integrator comprising an operational amplifier with a feedback capacitor connected between the output and the inverting input.

The A/D conversion unit 1110 is coupled to the integrator unit 1108 and receives the analog voltage outputs V_{MAC}. The A/D conversion unit 1110 digitizes the analog voltage outputs V_{MAC} to produce digital outputs D_{MAC} representing the digitized partial products. The A/D conversion unit 1110 converts the analog voltage values V_{MAC} into digital representations for subsequent processing by the reconstruction unit 1112. The A/D conversion unit 1110 may comprise an array of analog-to-digital converters, where each analog-to-digital converter has a resolution of 2p+log₂n bits, where p is a bit width of each bit-spliced portion of the first set of bit-spliced portions and the second set of bit-spliced portions, and n is the number of CIM blocks, to accommodate the accumulated partial products from multiple weight-input pairs. In some non-limiting examples, the A/D conversion unit 1110 may be implemented using successive approximation register (SAR) analog-to-digital converters, flash analog-to-digital converters, or sigma-delta analog-to-digital converters depending on the speed and resolution requirements of the MAC circuit 1100.

The reconstruction unit 1112 is coupled to the A/D conversion unit 1110 and receives the digital outputs D_{MAC}. The reconstruction unit 1112 combines the digitized partial products based on shift and add operations to reconstruct a full-precision MAC result Y_{MAC}. The reconstruction unit 1112 outputs the MAC result Y_{MAC} representing the multiply-accumulate computation of the digital operands processed by the plurality of CIM blocks. The shift and add operations performed by the reconstruction unit 1112 comprise a left shifting of a first subset of the digitized partial products by a first shift amount corresponding to a first significance level, a left shifting of a second subset of the digitized partial products by a second shift amount corresponding to a second significance level different from the first significance level, and an addition of the left-shifted first subset, the left-shifted second subset, and a third subset of the digitized partial products to produce the MAC result Y_{MAC}. The first shift amount is 2p bits and the second shift amount is p bits, where p is a bit width of each bit-spliced portion. In some non-limiting examples, the reconstruction unit 1112 may comprise a combinational logic circuit configured to perform the shift and add operations. The MAC result Y_{MAC} represents the computation Y_{MAC}=OP1a×OP2a+OP1b×OP2b+ . . .+OP1n×OP2n, which corresponds to a dot product of two n-element vectors.

The MAC circuit 1100 depicted in FIG. 11 follows the same architectural principles as the MAC circuit 802 depicted in the block diagram 800 of FIG. 8, using CIM block terminology. In both the MAC circuit 802 and the MAC circuit 1100, current outputs from corresponding bit positions across all multiplier circuits or CIM blocks are shorted together at multiple common nodes (one for each bit-splice index) before integration, and the integrator unit comprises multiple integrator circuits that accumulate the summed currents from each bit-splice position separately to produce multiple voltage outputs. For example, when the MAC circuit 1100 comprises three CIM blocks processing 8-bit operands split into four 2-bit portions, the summation node 1104 comprises four common nodes, the integrator unit 1108 comprises four integrator circuits, and the A/D conversion unit 1110 comprises four analog-to-digital converters. In some non-limiting examples, the MAC circuit 1100 may be implemented within an analog compute-in-memory (ACIM) system for neural network inference, where the first digital operands represent weight values of a neural network and the second digital operands represent input values for the neural network.

Reference throughout this specification to “an example” means that a particular feature, structure, or characteristic described in connection with the example is included in at least one embodiment of the present invention. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present invention may be referred to herein along with alternatives for the various components thereof. It is understood that such embodiments, examples, and alternatives are not to be construed as de facto equivalents of one another but are to be considered as separate and autonomous representations of the present invention.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the invention is not to be limited to the details given herein but may be modified within the scope and equivalents of the appended claims.

Those having skill in the art will appreciate that many changes may be made to the details of the above-described embodiments without departing from the underlying principles of the invention. The scope of the present invention should, therefore, be determined only by the following claims.

What is claimed is:

1. A multiplier circuit, comprising:
an array of current generation units, wherein each current generation unit of the array of current generation units is configured to generate a current output corresponding to a respective bit-spliced portion of a first set of bit-spliced portions of a first digital operand;
a signal generation unit configured to generate a set of pulse inputs corresponding to a second set of bit-spliced portions of a second digital operand;
a switching unit comprising an array of switches respectively coupled to the array of current generation units;
an integration unit comprising an array of integrator circuits respectively coupled to the array of switches, wherein
applying each pulse input of the set of pulse inputs to a respective switch of the array of switches in a systolic manner gates the current output from a respective current generation unit of the array of current generation units to a respective integrator circuit of the array of integrator circuits,
the array of integrator circuits is reset between successive cycles such that the array of integrator circuits produces, after each cycle of the successive cycles, a subset of voltage outputs of a set of voltage outputs, and
the set of voltage outputs corresponds to all pairwise partial products of the first set of bit-spliced portions and the second set of bit-spliced portions; and
a digital processing unit configured to:
digitize the set of voltage outputs into a set of digitized partial products; and
combine the set of digitized partial products based on binary shift and add operations to reconstruct a full-precision multiplication result of the first digital operand and the second digital operand.

2. The multiplier circuit of claim 1, wherein each current generation unit of the array of current generation units comprises a current digital-to-analog converter (DAC), and
the current DAC includes a set of binary-weighted current sources and a set of internal switches respectively coupled to the set of binary-weighted current sources.

3. The multiplier circuit of claim 2, wherein the set of internal switches is controlled by bits of the respective bit-spliced portion of the first digital operand.

4. The multiplier circuit of claim 3, wherein the current DAC of each current generation unit of the array of current generation units comprises memory cells configured to store the bits of the respective bit-spliced portion of the first digital operand.

5. The multiplier circuit of claim 1, wherein
the signal generation unit comprises a cascaded array of shift registers and an array of pulse width modulation circuits respectively coupled to the cascaded array of shift registers,
the cascaded array of shift registers is configured to sequentially shift each bit-spliced portion of the second set of bit-spliced portions to effectuate the systolic manner, and
each pulse width modulation circuit of the array of pulse width modulation circuits is configured to:
receive a bit-spliced portion of the second set of bit-spliced portions from a respective shift register of the cascaded array of shift registers; and
generate a respective pulse input of the set of pulse inputs based on the received bit-spliced portion.

6. The multiplier circuit of claim 5, wherein each pulse input of the set of pulse inputs has a pulse width corresponding to a value of a respective bit-spliced portion of the second set of bit-spliced portions.

7. The multiplier circuit of claim 1, wherein each integrator circuit of the array of integrator circuits is one of a capacitor-based circuit or an operational amplifier-based circuit.

8. The multiplier circuit of claim 1, wherein the first digital operand and the second digital operand are each N-bit operands, and each bit-spliced portion of the first set of bit-spliced portions and each bit-spliced portion of the second set of bit-spliced portions is a p-bit portion, wherein p is less than N.

9. The multiplier circuit of claim 8, wherein the first set of bit-spliced portions comprises N/p bit-spliced portions and the second set of bit-spliced portions comprises N/p bit-spliced portions.

10. The multiplier circuit of claim 1, wherein the digital processing unit comprises an array of analog-to-digital converters configured to digitize the set of voltage outputs into the set of digitized partial products.

11. The multiplier circuit of claim 10, wherein each analog-to-digital converter of the array of analog-to-digital converters has a resolution of 2p bits, wherein p is a bit width of each bit-spliced portion of the first set of bit-spliced portions and the second set of bit-spliced portions.

12. The multiplier circuit of claim 1, wherein the shift and add operations comprise:
a left shifting of a first subset of the set of digitized partial products by a first shift amount corresponding to a first significance level; and
a left shifting of a second subset of the set of digitized partial products by a second shift amount corresponding to a second significance level different from the first significance level, and
an addition of the left-shifted first subset, the left-shifted second subset, and a third subset of the set of digitized partial products to reconstruct the full-precision multiplication result.

13. The multiplier circuit of claim 12, wherein the first shift amount is 2p bits and the second shift amount is p bits, wherein p is a bit width of each bit-spliced portion of the first set of bit-spliced portions and the second set of bit-spliced portions.

14. The multiplier circuit of claim 1, wherein the applying of each pulse input of the set of pulse inputs to the respective switch of the array of switches in the systolic manner comprises:
in a first cycle of the successive cycles, applying a first pulse input of the set of pulse inputs to a first switch of the array of switches;
in a second cycle of the successive cycles, applying the first pulse input to a second switch of the array of switches and applying a second pulse input of the set of pulse inputs to the first switch; and
continuing a systolic propagation pattern through remaining cycles of the successive cycles until all pulse inputs of the set of pulse inputs are applied to all switches of the array of switches,
wherein the systolic propagation pattern comprises shifting each pulse input to a next switch of the array of switches while introducing a subsequent pulse input to the first switch in each successive cycle.

15. The multiplier circuit of claim 1, wherein the first digital operand represents a weight value of a neural network, and the second digital operand represents an input value for the neural network.

16. The multiplier circuit of claim 1, wherein
the signal generation unit is configured to interleave bit-spliced portions from successive instances of the second digital operand such that, during the successive cycles, bit-spliced portions of a current instance of the second digital operand and bit-spliced portions of a previous instance of the second digital operand propagate through the array of switches concurrently, and
each current generation unit of the array of current generation units maintains, across the successive cycles, the current output for the respective bit-spliced portion of the first digital operand.

17. The multiplier circuit of claim 1, wherein the digital processing unit comprises a combinational logic circuit configured to perform the shift and add operations.

18. The multiplier circuit of claim 1, wherein the multiplier circuit is configured to operate in a broadcast mode in which a same pulse input of the set of pulse inputs is applied simultaneously to all switches of the array of switches during a single cycle of the successive cycles.

19. A multiply-accumulate (MAC) circuit, comprising:
a plurality of multiplier circuits, each multiplier circuit of the plurality of multiplier circuits comprising:
an array of current generation units, wherein each current generation unit of the array of current generation units is configured to generate a current output corresponding to a respective bit-spliced portion of a first set of bit-spliced portions of a respective first digital operand;
a signal generation unit configured to generate a set of pulse inputs corresponding to a second set of bit-spliced portions of a respective second digital operand; and
a switching unit comprising an array of switches respectively coupled to the array of current generation units, wherein applying each pulse input of the set of pulse inputs to a respective switch of the array of switches gates the current output from a respective current generation unit of the array of current generation units;
a shared array of integrator circuits, wherein current outputs from corresponding bit positions across the plurality of multiplier circuits are shorted together before integration such that the shared array of integrator circuits accumulates summed currents from the plurality of multiplier circuits,
the shared array of integrator circuits is reset between successive cycles such that the shared array of integrator circuits produces, after each cycle of the successive cycles, a subset of voltage outputs of a set of voltage outputs, and
the set of voltage outputs corresponds to all pairwise partial products of the first set of bit-spliced portions and the second set of bit-spliced portions accumulated across the plurality of multiplier circuits;
an ADC array configured to digitize the set of voltage outputs from the shared array of integrator circuits into a set of digitized partial products; and
a digital reconstruction unit configured to combine the set of digitized partial products based on binary shift and add operations to produce a MAC result.

20. A method for performing hybrid analog-digital multiplication, the method comprising:
generating, by an array of current generation units, a plurality of current outputs, wherein each current output corresponds to a respective bit-spliced portion of a first set of bit-spliced portions of a first digital operand;
generating, by a signal generation unit, a set of pulse inputs corresponding to a second set of bit-spliced portions of a second digital operand;
applying each pulse input of the set of pulse inputs to a respective switch of an array of switches in a systolic manner to gate a current output of the plurality of current outputs from a respective current generation unit of the array of current generation units to a respective integrator circuit of an array of integrator circuits;
resetting the array of integrator circuits between successive cycles such that the array of integrator circuits produces, after each cycle of the successive cycles, a subset of voltage outputs of a set of voltage outputs,
wherein the set of voltage outputs corresponds to all pairwise partial products of the first set of bit-spliced portions and the second set of bit-spliced portions;
digitizing, by a digital processing unit, the set of voltage outputs into a set of digitized partial products; and
combining, by the digital processing unit, the set of digitized partial products based on shift and add operations to reconstruct a full-precision multiplication result of the first digital operand and the second digital operand.
